(19) United States
(12) Patent Application Publication
(10) Pub. No.: US 2025/0385679 A1
(43) Pub. Date: Dec. 18, 2025

(54) SIGNAL TRANSMITTER, ELECTRONIC DEVICE, VEHICLE, AND INSULATED GATE DRIVER INTEGRATED CIRCUIT

(71) Applicant: ROHM CO., LTD., Kyoto (JP)

(72) Inventor: Yosuke YAMANAKA, Kyoto (JP)

(21) Appl. No.: 19/235,068

(22) Filed: Jun. 11, 2025

(30) Foreign Application Priority Data
Jun. 18, 2024 (JP) 2024-097930

(51) Int. Cl. H03K 21/00; H03K 5/00; H03K 5/01

(52) U.S. Cl. CPC H03K 21/00; H03K 5/01; H03K 2005/00013

(57) ABSTRACT

A signal transmitter includes: a transmission circuit; a reception circuit; and a plurality of insulating elements configured to transmit a plurality of signals, respectively, from the transmission circuit to the reception circuit while insulating between the transmission circuit and the reception circuit, wherein the transmission circuit includes: an oscillator circuit configured to generate a plurality of clock signals having different phases; and a plurality of driving circuits configured to drive the plurality of insulating elements in synchronization with the plurality of clock signals, respectively.

### CROSS-REFERENCE TO RELATED APPLICATION

The present invention claims priority under 35 U.S.C. § 119 Japanese Patent Application No. 2024-097930, filed on Jun. 18, 2024, the entire contents of which are incorporated herein by reference.

### TECHNICAL FIELD

The present disclosure relates to a signal transmitter, an electronic device, a vehicle, and an insulated gate driver integrated circuit (IC).

### BACKGROUND

In the related art, signal transmitters that transmit signals between a primary circuit system and a secondary circuit system while electrically insulating between the primary circuit system and the secondary circuit system have been used in various applications (such as power supplies or motor drivers).

### BRIEF DESCRIPTION OF DRAWINGS

The accompanying drawings, which are incorporated in and constitute a part of the specification, illustrate embodiments of the present disclosure.

FIG. 1 is a diagram showing a basic configuration of a signal transmitter.

FIG. 2 is a diagram showing a basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view showing a layer in which a low potential coil is formed in the semiconductor device shown in FIG. 3.

FIG. 6 is a plan view showing a layer in which a high potential coil is formed in the semiconductor device shown in FIG. 3.

FIG. 7 is a cross-sectional view taken along line VIII-VIII in FIG. 6.

FIG. 8 is an enlarged view showing region XIII (isolation structure) in FIG. 7.

FIG. 9 is a diagram schematically showing a layout example of the transformer chip.

FIG. 10 is a diagram showing an example of a configuration of the signal transmitter.

FIG. 11 is a diagram showing an example of a pulse generation operation.

FIG. 12 is a diagram showing an example of a configuration of a reception circuit.

FIG. 13 is a diagram showing an example of multi-channel drive.

FIG. 14 is a diagram showing a state in which a signal is attenuated in the multi-channel drive.

FIG. 15 is a diagram showing a comparative example of a transmission circuit.

FIG. 16 is a diagram showing an example of a drive timing in the comparative example.

FIG. 17 is a diagram showing a transmission circuit according to a first embodiment.

FIG. 18 is a diagram showing an example of a drive timing in the first embodiment.

FIG. 19 is a diagram showing a transmission circuit according to a second embodiment.

FIG. 20 is a diagram showing an example of a drive timing in the second embodiment.

FIG. 21 is a diagram showing a transmission circuit according to a third embodiment.

FIG. 22 is a diagram showing an example of a drive timing in the third embodiment.

FIG. 23 is a diagram showing a transmission circuit according to a fourth embodiment.

FIG. 24 is a diagram showing a state in which drive timings overlap.

FIG. 25 is a diagram showing temperature dependency of an oscillation frequency.

FIG. 26 is a diagram showing an exterior of a vehicle.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Signal Transmitter (Basic Configuration)

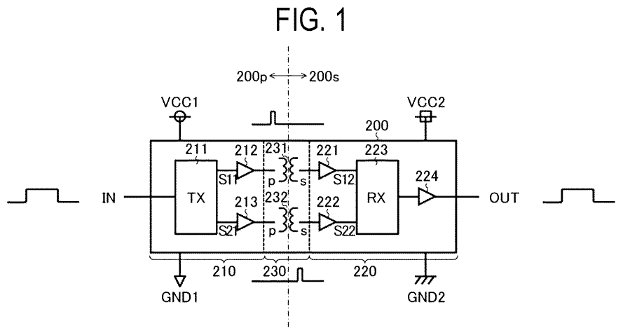

FIG. 1 shows a basic configuration of a signal transmitter. The signal transmitter 200 of this configuration example is a semiconductor integrated circuit device (so-called insulated gate driver IC) configured to, while insulating between a primary circuit system 200p (VCC1-GND1 system) and a secondary circuit system 200s (VCC2-GND2 system), transmit a pulse signal from the primary circuit system 200p to the secondary circuit system 200s and drive a gate of a switch element (not shown) provided in the secondary circuit system 200s. For example, the signal transmitter 200 includes a controller chip 210, a driver chip 220, and a transformer chip 230, which are sealed in a single package.

The controller chip 210 is a semiconductor chip that operates by receiving a power supply voltage VCCI (e.g., a maximum of 7 V based on GND1). The controller chip 210 includes, for example, a pulse transmission circuit 211 and buffers 212 and 213, which are integrated therein.

The pulse transmission circuit 211 is a pulse generator that generates transmission pulse signals S11 and S21 in response to an input pulse signal IN. More specifically, when the pulse transmission circuit 211 notifies that the input pulse signal IN is at a high level, it pulse-drives the transmission pulse signal S11 (outputs a single or a plurality of transmission pulses), and when the pulse transmission circuit 211 notifies that the input pulse signal IN is at a low level, it pulse-drives the transmission pulse signal S21. That is, the pulse transmission circuit 211 pulse-drives either the transmission pulse signal S11 or the transmission pulse signal S21 in response to a logic level of the input pulse signal IN.

The buffer 212 receives the transmission pulse signal S11 from the pulse transmission circuit 211 and pulse-drives the transformer chip 230 (specifically, the transformer 231).

The buffer 213 receives the transmission pulse signal S21 from the pulse transmission circuit 211 and pulse-drives the transformer chip 230 (specifically, the transformer 232).

The driver chip 220 is a semiconductor chip that operates by receiving a power supply voltage VCC2 (e.g., a maximum of 30 V based on GND2). The driver chip 220 includes buffers 221 and 222, a pulse reception circuit 223, and a driver 224, which are integrated therein.

The buffer 221 shapes a waveform of a reception pulse signal S12 induced in the transformer chip 230 (specifically, the transformer 231) and outputs the result to the pulse reception circuit 223.

The buffer 222 shapes a waveform of a reception pulse signal S22 induced in the transformer chip 230 (specifically, the transformer 232) and outputs the result to the pulse reception circuit 223.

The pulse reception circuit 223 generates an output pulse signal OUT by driving the driver 224 in response to the reception pulse signals S12 and S22 input via the buffers 221 and 222. More specifically, the pulse reception circuit 223 drives the driver 224 so as to raise the output pulse signal OUT to a high level in response to pulse driving of the reception pulse signal S12, and to lower the output pulse signal OUT to a low level in response to pulse driving of the reception pulse signal S22. That is, the pulse reception circuit 223 switches a logic level of the output pulse signal OUT in response to the logic level of the input pulse signal IN. For example, an RS flip-flop may be suitably used as the pulse reception circuit 223.

The driver 224 generates the output pulse signal OUT based on drive control of the pulse reception circuit 223.

The transformer chip 230 provides DC insulation between the controller chip 210 and the driver chip 220 by using transformers 231 and 232, and outputs the transmission pulse signals S11 and S21 input from the pulse transmission circuit 211 to the pulse reception circuit 223 as the reception pulse signals S12 and S22, respectively. In this specification, “DC insulation” means that objects to be insulated are not connected by a conductor.

More specifically, the transformer 231 outputs the reception pulse signal S12 from a secondary coil 231s in response to the transmission pulse signal S11 input to a primary coil 231p, while the transformer 232 outputs the reception pulse signal S22 from a secondary coil 232s in response to the transmission pulse signal S21 input to a primary coil 232p.

As described above, due to characteristics of the spiral coils used for insulated communication, the input pulse signal IN is separated into two transmission pulse signals S11 and S21 (corresponding to a rise signal and a fall signal), and then transmitted from the primary circuit system 200p to the secondary circuit system 200s via the two transformers 231 and 232.

The signal transmitter 200 of this configuration example includes the transformer chip 230, which is equipped with only the transformers 231 and 232, independently of the controller chip 210 and the driver chip 220. These three chips are sealed in a single package.

With this configuration, the controller chip 210 and the driver chip 220 may both be formed using a general low-to-medium voltage withstand process (withstand voltage of several volts to several tens of volts), which eliminates the need to use a dedicated high voltage withstand process (withstand voltage of several kV), making it possible to reduce a manufacturing cost.

Further, the signal transmitter 200 may be suitably used, for example, in a power supply or a motor driver for on-vehicle equipment mounted on a vehicle. The above-mentioned vehicle includes not only an engine vehicle but also an electric vehicle (xEV such as BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

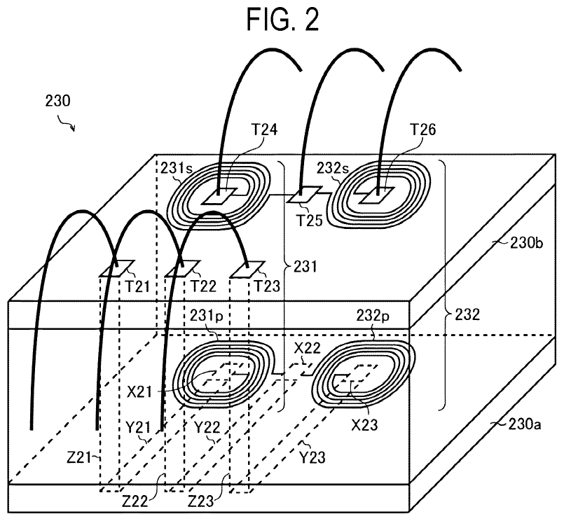

Next, a basic structure of the transformer chip 230 is described. FIG. 2 is a diagram showing the basic structure of the transformer chip 230. In the transformer chip 230 of this figure, the transformer 231 includes the primary coil 231p and the secondary coil 231s that face each other in a vertical direction. The transformer 232 includes the primary coil 232p and the secondary coil 232s that face each other in the vertical direction.

The primary coils 231p and 232p are both formed in a first wiring layer (lower layer) 230a of the transformer chip 230. The secondary coils 231s and 232s are both formed in a second wiring layer (upper layer in this figure) 230b of the transformer chip 230. Further, the secondary coil 231s is disposed directly above the primary coil 231p to face the primary coil 231p. The secondary coil 232s is disposed directly above the primary coil 232p to face the primary coil 232p.

The primary coil 231p is laid in a spiral shape so as to surround a periphery of an internal terminal X21 in a clockwise direction with a first end thereof as a start point connected to the internal terminal X21, and is connected to an internal terminal X22 at a second end thereof corresponding to an end point. On the other hand, the primary coil 232p is laid in a spiral shape so as to surround a periphery of an internal terminal X23 in a counterclockwise direction with a first end thereof as a start point connected to the internal terminal X23, and is connected to the internal terminal X22 at a second end thereof corresponding to an end point. The internal terminals X21, X22, and X23 are arranged linearly in the illustrated order.

The internal terminal X21 is connected to an external terminal T21 of a second layer 230b through a conductive wiring Y21 and a via Z21. The internal terminal X22 is connected to an external terminal T22 of the second layer 230b via a conductive wiring Y22 and a via Z22. The internal terminal X23 is connected to an external terminal T23 of the second layer 230b via a conductive wiring Y23 and a via Z23. The external terminals T21 to T23 are arranged linearly and are used for wire bonding with the controller chip 210.

The secondary coil 231s is laid in a spiral shape so as to surround a periphery of an external terminal T24 in a counterclockwise direction with a first end thereof as a start point connected to the external terminal T24, and is connected to an external terminal T25 at a second end corresponding an end point. On the other hand, the secondary coil 232s is laid in a spiral shape so as to surround a periphery of an external terminal T26 in a clockwise direction with a first end thereof as a start point connected to the external terminal T26, and is connected to the external terminal T25 at a second end thereof corresponding an end point. The external terminals T24, T25, and T26 are arranged linearly in the illustrated order, and are used for wire bonding with the driver chip 220.

The secondary coils 231s and 232s are AC-connected to the primary coils 231p and 232p by magnetic coupling, and are DC-insulated from the primary coils 231p and 232p. That is, the driver chip 220 is AC-connected to the controller chip 210 via the transformer chip 230, and is DC-insulated from the controller chip 210 by the transformer chip 230.

### Transformer Chip (Two-Channel Type)

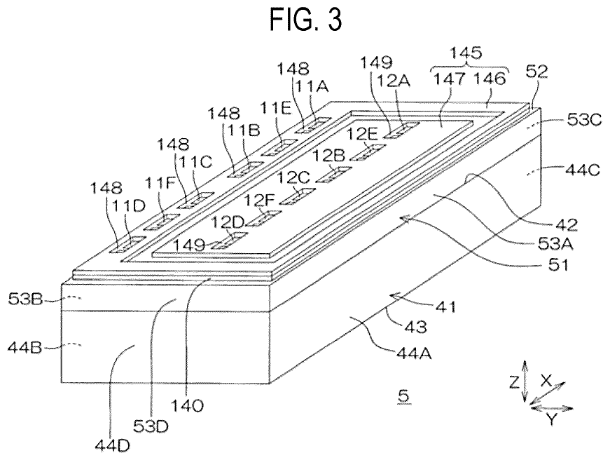

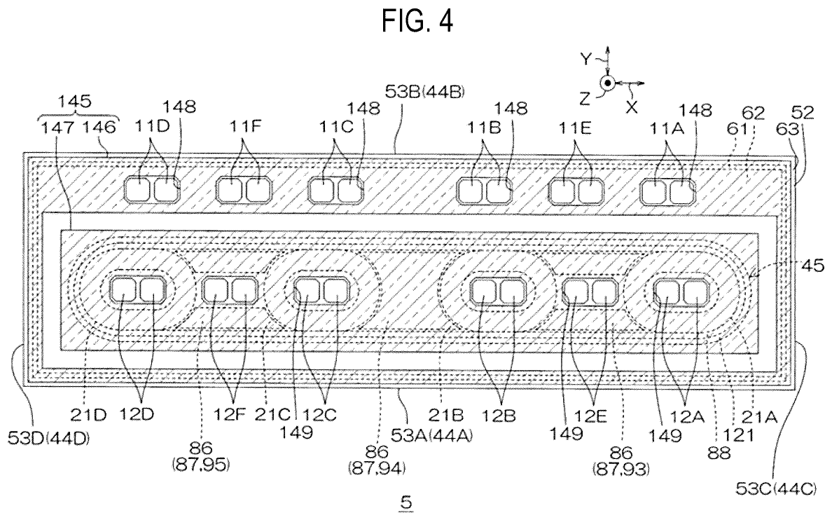

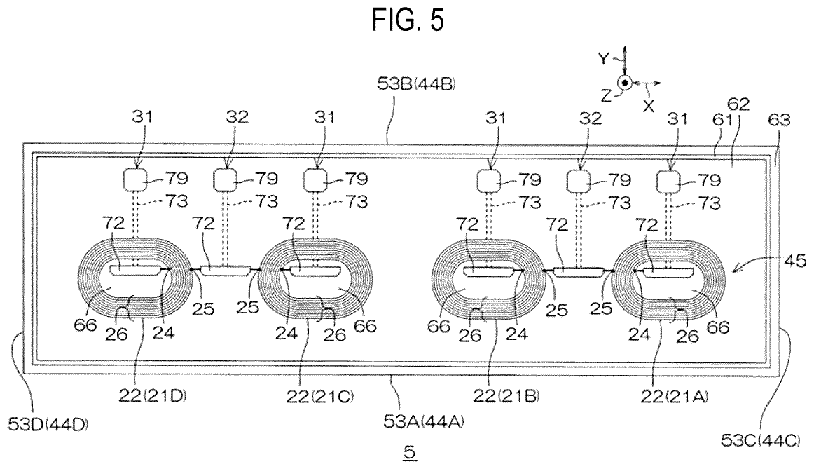

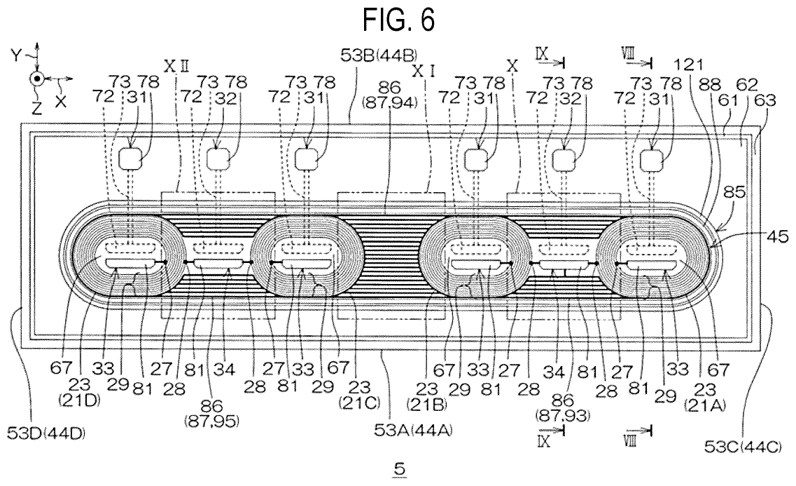

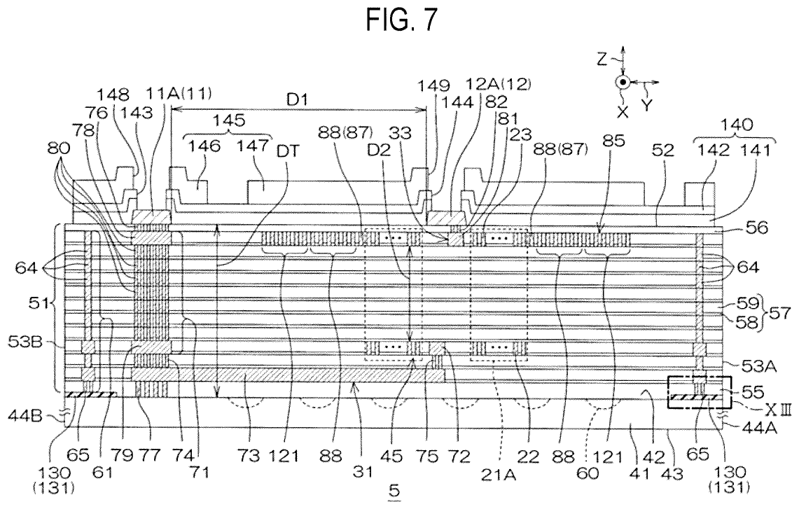

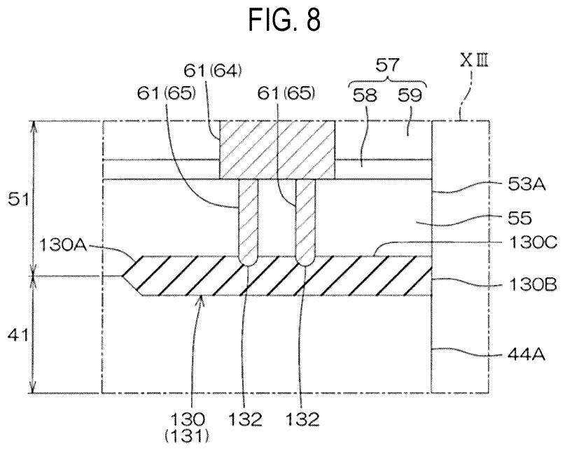

FIG. 3 is a perspective view showing a semiconductor device 5 used as a two-channel type transformer chip. FIG. 4 is a plan view of the semiconductor device 5 shown in FIG. 3. FIG. 5 is a plan view showing a layer in which a low potential coil 22 (corresponding to the primary coil of the transformer) is formed in the semiconductor device 5 shown in FIG. 3. FIG. 6 is a plan view showing a layer in which a high potential coil 23 (corresponding to the secondary coil of the transformer) is formed in the semiconductor device 5 shown in FIG. 3. FIG. 7 is a cross-sectional view taken along line VIII-VIII in FIG. 6. FIG. 8 is an enlarged view of region XIII in FIG. 7, showing an isolation structure 130.

Referring to FIGS. 3 to 7, the semiconductor device 5 includes a rectangular parallelepiped semiconductor chip 41. The semiconductor chip 41 includes at least one selected from the group of silicon, a wide band gap semiconductor, and a compound semiconductor.

The wide band gap semiconductor is made of a semiconductor whose band gap exceeds that of silicon (about 1.12 eV). The band gap of the wide band gap semiconductor is preferably 2.0 eV or more. The wide band gap semiconductor may be SiC (silicon carbide). The compound semiconductor may be a III-V Group compound semiconductor. The compound semiconductor may include at least one selected from the group of AlN (aluminum nitride), InN (indium nitride), GaN (gallium nitride), and GaAs (gallium arsenide).

In this embodiment, the semiconductor chip 41 includes a silicon semiconductor substrate. The semiconductor chip 41 may be an epitaxial substrate including a layered structure including a silicon semiconductor substrate and a silicon epitaxial layer. A conductivity type of the semiconductor substrate may be n-type or p-type. The epitaxial layer may be n-type or p-type.

The semiconductor chip 41 includes a first main surface 42 on one side, a second main surface 43 on the other side, and chip sidewalls 44A to 44D connecting the first main surface 42 and the second main surface 43. The first main surface 42 and the second main surface 43 are formed in a quadrangular shape (rectangular shape in this embodiment) in a plan view seen from their normal direction Z (hereinafter simply referred to as “in a plan view”).

The chip sidewalls 44A to 44D include a first chip sidewall 44A, a second chip sidewall 44B, a third chip sidewall 44C, and a fourth chip sidewall 44D. The first chip sidewall 44A and the second chip sidewall 44B form long sides of the semiconductor chip 41. The first chip sidewall 44A and the second chip sidewall 44B extend along a first direction X and face each other in a second direction Y. The third chip sidewall 44C and the fourth chip sidewall 44D form short sides of the semiconductor chip 41. The third chip sidewall 44C and the fourth chip sidewall 44D extend in the second direction Y and face each other in the first direction X. The chip sidewalls 44A to 44D are made of ground surfaces.

The semiconductor device 5 further includes an insulating layer 51 formed over the first main surface 42 of the semiconductor chip 41. The insulating layer 51 includes an insulating main surface 52 and insulating sidewalls 53A to 53D. The insulating main surface 52 is formed in a quadrangular shape (rectangular shape in this embodiment) that matches the first main surface 42 in a plan view. The insulating main surface 52 extends parallel to the first main surface 42.

The insulating sidewalls 53A to 53D include a first insulating sidewall 53A, a second insulating sidewall 53B, a third insulating sidewall 53C, and a fourth insulating sidewall 53D. The insulating sidewalls 53A to 53D extend from a periphery of the insulating main surface 52 toward the semiconductor chip 41 and are continuous with the chip sidewalls 44A to 44D. Specifically, the insulating sidewalls 53A to 53D are formed flush with the chip sidewalls 44A to 44D. The insulating sidewalls 53A to 53D form ground surfaces that are flush with the chip sidewalls 44A to 44D.

The insulating layer 51 is made of a multi-layer insulating laminate structure including a lowermost insulating layer 55, an uppermost insulating layer 56, and a plurality of (eleven in this embodiment) interlayer insulating layers 57. The lowermost insulating layer 55 is an insulating layer that directly covers the first main surface 42. The uppermost insulating layer 56 is an insulating layer that forms the insulating main surface 52. The plurality of interlayer insulating layers 57 are insulating layers interposed between the lowermost insulating layer 55 and the uppermost insulating layer 56. In this embodiment, the lowermost insulating layer 55 includes a single-layer structure containing silicon oxide. In this embodiment, the uppermost insulating layer 56 includes a single-layer structure containing silicon oxide. Each of a thickness of the lowermost insulating layer 55 and a thickness of the uppermost insulating layer 56 may be 1 μm or more and 3 μm or less (e.g., about 2 μm).

Each of the interlayer insulating layers 57 includes a laminated structure including a first insulating layer 58 on a side of the lowermost insulating layer 55 and a second insulating layer 59 on a side of the uppermost insulating layer 56. The first insulating layer 58 may contain silicon nitride. The first insulating layer 58 is formed as an etching stopper layer for the second insulating layer 59. A thickness of the first insulating layer 58 may be 0.1 μm or more and 1 μm or less (e.g., about 0.3 μm).

The second insulating layer 59 is formed over the first insulating layer 58. The second insulating layer 59 contains an insulating material different from that of the first insulating layer 58. The second insulating layer 59 may contain silicon oxide. A thickness of the second insulating layer 59 may be 1 μm or more and 3 μm or less (e.g., about 2 μm). The thickness of the second insulating layer 59 is preferably greater than the thickness of the first insulating layer 58.

A total thickness DT of the insulating layer 51 may be 5 μm or more and 50 μm or less. The total thickness DT of the insulating layer 51 and the number of layers stacked for the interlayer insulating layer 57 are arbitrary and are adjusted according to a dielectric withstand voltage (dielectric breakdown resistance) to be realized. In addition, insulating materials of the lowermost insulating layer 55, the uppermost insulating layer 56, and the interlayer insulating layers 57 are arbitrary and are not limited to a specific insulating material.

The semiconductor device 5 includes a first functional device 45 formed in the insulating layer 51. The first functional device 45 includes one or more (a plurality in this embodiment) transformers 21 (corresponding to the aforementioned transformer). In other words, the semiconductor device 5 is a multi-channel device including a plurality of transformers 21. The plurality of transformers 21 are formed in an inner portion of the insulating layer 51 at intervals from the insulating sidewalls 53A-53D. The plurality of transformers 21 are formed at intervals in the first direction X.

Specifically, the plurality of transformers 21 include a first transformer 21A, a second transformer 21B, a third transformer 21C, and a fourth transformer 21D, which are formed in the named order from a side of the insulating sidewall 53C toward a side of the insulating sidewall 53D in a plan view. The plurality of transformers 21A to 21D include the same structure. In the following, the structure of the first transformer 21A is described as an example. Description of structures of the second transformer 21B, the third transformer 21C, and the fourth transformer 21D is omitted since the description of the structure of the first transformer 21A applies mutatis mutandis.

Referring to FIGS. 5 to 7, the first transformer 21A includes the low potential coil 22 and the high potential coil 23. The low potential coil 22 is formed in the insulating layer 51. The high potential coil 23 is formed in the insulating layer 51 so as to face the low potential coil 22 in the normal direction Z. In this embodiment, the low potential coil 22 and the high potential coil 23 are formed in a region sandwiched between the lowermost insulating layer 55 and the uppermost insulating layer 56 (i.e., at a plurality of interlayer insulating layers 57).

The low potential coil 22 is formed at a side of the lowermost insulating layer 55 (semiconductor chip 41) within the insulating layer 51, and the high potential coil 23 is formed at a side of the uppermost insulating layer 56 (insulating main surface 52) with respect to the low potential coil 22 within the insulating layer 51. In other words, the high potential coil 23 faces the semiconductor chip 41 with the low potential coil 22 interposed therebetween. The low potential coil 22 and the high potential coil 23 may be disposed in any desired locations. The high potential coil 23 may face the low potential coil 22 with one or more interlayer insulating layers 57 interposed therebetween.

A distance between the low potential coil 22 and the high potential coil 23 (i.e., the number layers stacked for the interlayer insulating layers 57) is appropriately adjusted according to a dielectric withstand voltage and an electric field strength between the low potential coil 22 and the high potential coil 23. In this embodiment, the low potential coil 22 is formed in the third interlayer insulating layer 57 counting from the side of the lowermost insulating layer 55. In this embodiment, the high potential coil 23 is formed in the first interlayer insulating layer 57 counting from the side of the uppermost insulating layer 56.

The low potential coil 22 is embedded in the interlayer insulating layer 57 while penetrating through the first insulating layer 58 and the second insulating layer 59. The low potential coil 22 includes a first inner end 24, a first outer end 25, and a first spiral portion 26 wound in a spiral shape between the first inner end 24 and the first outer end 25. The first spiral portion 26 is wound in a spiral shape extending in an elliptical shape (oval shape) in a plan view. A portion forming an innermost periphery of the first spiral portion 26 defines a first inner region 66 having an elliptical shape in a plan view.

The number of turns of the first spiral portion 26 may be five or more and thirty or less. A width of the first spiral portion 26 may be 0.1 μm or more and 5 μm or less. The width of the first spiral portion 26 is preferably 1 μm or more and 3 μm or less. The width of the first spiral portion 26 is defined by the width in a direction perpendicular to the spiral direction. A first winding pitch of the first spiral portion 26 may be 0.1 μm or more and 5 μm or less. The first winding pitch is preferably 1 μm or more and 3 μm or less. The first winding pitch is defined by a distance between two adjacent portions of the first spiral portion 26 in a direction perpendicular to the spiral direction.

A winding shape of the first spiral portion 26 and a plan-view shape of the first inner region 66 are arbitrary and are not limited to the ones shown in FIG. 5 and the like. The first spiral portion 26 may be wound in a polygonal shape such as a triangular shape or a rectangular shape, or in a circular shape in a plan view. The first inner region 66 may be defined in a polygonal shape such as a triangular shape or a rectangular shape, or in a circular shape in a plan view, depending on the winding shape of the first spiral portion 26.

The low potential coil 22 may contain at least one selected from the group of titanium, titanium nitride, copper, aluminum, and tungsten. The low potential coil 22 may include a laminated structure including a barrier layer and a main body layer. The barrier layer defines a recess space in the interlayer insulating layers 57. The barrier layer may contain at least one selected from the group of titanium and titanium nitride. The main body layer may contain at least one selected from the group of copper, aluminum, and tungsten.

The high potential coil 23 is embedded in the interlayer insulating layer 57 while penetrating through the first insulating layer 58 and the second insulating layer 59. The high potential coil 23 includes a second inner end 27, a second outer end 28, and a second spiral portion 29 wound in a spiral shape between the second inner end 27 and the second outer end 28. The second spiral portion 29 is wound in a spiral shape extending in an elliptical shape (oval shape) in a plan view. In this embodiment, a portion forming an innermost periphery of the second spiral portion 29 defines a second inner region 67 that is elliptical in a plan view. The second inner region 67 of the second spiral portion 29 faces the first inner region 66 of the first spiral portion 26 in the normal direction Z.

The number of turns of the second spiral portion 29 may be five or more and thirty or less. The number of turns of the second spiral portion 29 relative to the number of turns of the first spiral portion 26 is adjusted according to a voltage value to be stepped up. It is preferable that the number of turns of the second spiral portion 29 exceeds the number of turns of the first spiral portion 26. Of course, the number of turns of the second spiral portion 29 may be less than the number of turns of the first spiral portion 26 or may be equal to the number of turns of the first spiral portion 26.

A width of the second spiral portion 29 may be 0.1 μm or more and 5 μm or less. The width of the second spiral portion 29 is preferably 1 μm or more and 3 μm or less. The width of the second spiral portion 29 is defined by the width in a direction perpendicular to the spiral direction. The width of the second spiral portion 29 is preferably equal to the width of the first spiral portion 26.

A second winding pitch of the second spiral portion 29 may be 0.1 μm or more and 5 μm or less. The second winding pitch is preferably 1 μm or more and 3 μm or less. The second winding pitch is defined by a distance between two adjacent portions of the second spiral portion 29 in a direction perpendicular to the spiral direction. The second winding pitch is preferably equal to the first winding pitch of the first spiral portion 26.

A winding shape of the second spiral portion 29 and a plan-view shape of the second inner region 67 are arbitrary and are not limited to the ones shown in FIG. 6 and the like. The second spiral portion 29 may be wound in a polygonal shape such as a triangular shape or a rectangular shape, or a circular shape in a plan view. The second inner region 67 may be defined in a polygonal shape such as a triangular shape or a rectangular shape, or a circular shape in a plan view, depending on the winding shape of the second spiral portion 29.

The high potential coil 23 is preferably formed of the same conductive material as the low potential coil 22. That is, similarly to the low potential coil 22, the high potential coil 23 preferably includes a barrier layer and a main body layer.

Referring to FIG. 4, the semiconductor device 5 includes a plurality of (twelve in this figure) low potential terminals 11 and a plurality of (twelve in this figure) high potential terminals 12. The low potential terminals 11 are electrically connected to the low potential coils 22 of the corresponding transformers 21A to 21D, respectively. The high potential terminals 12 are electrically connected to the high potential coils 23 of the corresponding transformers 21A to 21D, respectively.

The low potential terminals 11 are formed over the insulating main surface 52 of the insulating layer 51. Specifically, the low potential terminals 11 are formed in a region at a side of the insulating sidewall 53B at intervals in the second direction Y from the transformers 21A to 21D, and are arranged at intervals in the first direction X.

The low potential terminals 11 include a first low potential terminal 11A, a second low potential terminal 11B, a third low potential terminal 11C, a fourth low potential terminal 11D, a fifth low potential terminal 11E, and a sixth low potential terminal 11F. In this embodiment, two of each of the low potential terminals 11A to 11F are formed. The number of the low potential terminals 11A to 11F is arbitrary.

The first low potential terminal 11A faces the first transformer 21A in the second direction Y in a plan view. The second low potential terminal 11B faces the second transformer 21B in the second direction Y in a plan view. The third low potential terminal 11C faces the third transformer 21C in the second direction Y in a plan view. The fourth low potential terminal 11D faces the fourth transformer 21D in the second direction Y in a plan view. The fifth low potential terminal 11E is formed in a region between the first low potential terminal 11A and the second low potential terminal 11B in a plan view. The sixth low potential terminal 11F is formed in a region between the third low potential terminal 11C and the fourth low potential terminal 11D in a plan view.

The first low potential terminal 11A is electrically connected to the first inner end 24 of the first transformer 21A (low potential coil 22). The second low potential terminal 11B is electrically connected to the first inner end 24 of the second transformer 21B (low potential coil 22). The third low potential terminal 11C is electrically connected to the first inner end 24 of the third transformer 21C (low potential coil 22). The fourth low potential terminal 11D is electrically connected to the first inner end 24 of the fourth transformer 21D (low potential coil 22).

The fifth low potential terminal 11E is electrically connected to the first outer end 25 of the first transformer 21A (low potential coil 22) and the first outer end 25 of the second transformer 21B (low potential coil 22). The sixth low potential terminal 11F is electrically connected to the first outer end 25 of the third transformer 21C (low potential coil 22) and the first outer end 25 of the fourth transformer 21D (low potential coil 22).

The plurality of high potential terminals 12 are formed over the insulating main surface 52 of the insulating layer 51 at intervals from the plurality of low potential terminals 11. Specifically, the plurality of high potential terminals 12 are formed in a region at a side of the insulating sidewall 53A at intervals from the plurality of low potential terminals 11 in the second direction Y, and are arranged at intervals in the first direction X.

The plurality of high potential terminals 12 are formed in regions adjacent to the corresponding transformers 21A to 21D in a plan view. The high potential terminals 12 being adjacent to the transformers 21A to 21D means that distances between the high potential terminals 12 and the transformers 21 in a plan view are less than distances between the low potential terminals 11 and the high potential terminals 12.

Specifically, the plurality of high potential terminals 12 are formed at intervals along the first direction X so as to face the plurality of transformers 21A to 21D along the first direction X in a plan view. More specifically, the plurality of high potential terminals 12 are formed at intervals along the first direction X so as to be located in the second inner region 67 of the high potential coil 23 and in a region between adjacent high potential coils 23 in a plan view. As a result, the plurality of high potential terminals 12 are arranged in a line with the plurality of transformers 21A to 21D in the first direction X in a plan view.

The plurality of high potential terminals 12 include a first high potential terminal 12A, a second high potential terminal 12B, a third high potential terminal 12C, a fourth high potential terminal 12D, a fifth high potential terminal 12E, and a sixth high potential terminal 12F. In this embodiment, two of each of the plurality of high potential terminals 12A to 12F are formed. The number of the plurality of high potential terminals 12A to 12F is arbitrary.

The first high potential terminal 12A is formed in the second inner region 67 of the first transformer 21A (high potential coil 23) in a plan view. The second high potential terminal 12B is formed in the second inner region 67 of the second transformer 21B (high potential coil 23) in a plan view. The third high potential terminal 12C is formed in the second inner region 67 of the third transformer 21C (high potential coil 23) in a plan view. The fourth high potential terminal 12D is formed in the second inner region 67 of the fourth transformer 21D (high potential coil 23) in a plan view. The fifth high potential terminal 12E is formed in a region between the first transformer 21A and the second transformer 21B in a plan view. The sixth high potential terminal 12F is formed in a region between the third transformer 21C and the fourth transformer 21D in a plan view.

The first high potential terminal 12A is electrically connected to the second inner end 27 of the first transformer 21A (high potential coil 23). The second high potential terminal 12B is electrically connected to the second inner end 27 of the second transformer 21B (high potential coil 23). The third high potential terminal 12C is electrically connected to the second inner end 27 of the third transformer 21C (high potential coil 23). The fourth high potential terminal 12D is electrically connected to the second inner end 27 of the fourth transformer 21D (high potential coil 23).

The fifth high potential terminal 12E is electrically connected to the second outer end 28 of the first transformer 21A (high potential coil 23) and the second outer end 28 of the second transformer 21B (high potential coil 23). The sixth high potential terminal 12F is electrically connected to the second outer end 28 of the third transformer 21C (high potential coil 23) and the second outer end 28 of the fourth transformer 21D (high potential coil 23).

Referring to FIGS. 5 to 7, the semiconductor device 5 includes a first low potential wiring 31, a second low potential wiring 32, a first high potential wiring 33, and a second high potential wiring 34, each of which is formed in the insulating layer 51. In this embodiment, a plurality of the first low potential wirings 31, a plurality of the second low potential wirings 32, a plurality of the first high potential wirings 33, and a plurality of the second high potential wirings 34 are formed.

The first low potential wiring 31 and the second low potential wiring 32 fix the low potential coil 22 of the first transformer 21A and the low potential coil 22 of the second transformer 21B to the same potential. The first low potential wiring 31 and the second low potential wiring 32 also fix the low potential coil 22 of the third transformer 21C and the low potential coil 22 of the fourth transformer 21D to the same potential. In this embodiment, the first low potential wiring 31 and the second low potential wiring 32 fix all of the low potential coils 22 of the transformers 21A to 21D to the same potential.

The first high potential wiring 33 and the second high potential wiring 34 fix the high potential coil 23 of the first transformer 21A and the high potential coil 23 of the second transformer 21B to the same potential. The first high potential wiring 33 and the second high potential wiring 34 also fix the high potential coil 23 of the third transformer 21C and the high potential coil 23 of the fourth transformer 21D to the same potential. In this embodiment, the first high potential wiring 33 and the second high potential wiring 34 fix all of the high potential coils 23 of the transformers 21A to 21D to the same potential.

The plurality of first low potential wirings 31 are electrically connected to the corresponding low potential terminals 11A to 11D and the first inner ends 24 of the corresponding transformers 21A to 21D (low potential coils 22), respectively. The plurality of first low potential wirings 31 include the same structure. In the following, the structure of the first low potential wiring 31 connected to the first low potential terminal 11A and the first transformer 21A is described as an example. The description of the structures of the other first low potential wirings 31 is omitted since the description of the structure of the first low potential wiring 31 connected to the first transformer 21A applies mutatis mutandis.

The first low potential wiring 31 includes a penetration wiring 71, a low potential connection wiring 72, a lead-out wiring 73, a first connection plug electrode 74, a second connection plug electrode 75, one or more (a plurality in this embodiment) pad plug electrodes 76, and one or more (a plurality in this embodiment) substrate plug electrodes 77.

The penetration wiring 71, the low potential connection wiring 72, the lead-out wiring 73, the first connection plug electrode 74, the second connection plug electrode 75, the pad plug electrodes 76, and the substrate plug electrodes 77 are preferably made of the same conductive material as the low potential coil 22 and the like. In other words, each of the penetration wiring 71, the low potential connection wiring 72, the lead-out wiring 73, the first connection plug electrode 74, the second connection plug electrode 75, the pad plug electrodes 76, and the substrate plug electrodes 77 preferably includes a barrier layer and a main body layer, similarly to the low potential coil 22 and the like.

The penetration wiring 71 penetrates the plurality of interlayer insulating layers 57 in the insulating layer 51 and extends in a columnar shape extending along the normal direction Z. In this embodiment, the penetration wiring 71 is formed in a region between the lowermost insulating layer 55 and the uppermost insulating layer 56 in the insulating layer 51. The penetration wiring 71 includes an upper end at a side of the uppermost insulating layer 56 and a lower end at a side of the lowermost insulating layer 55. The upper end of the penetration wiring 71 is formed in the same interlayer insulating layer 57 as the high potential coil 23 and is covered by the uppermost insulating layer 56. The lower end of the penetration wiring 71 is formed in the same interlayer insulating layer 57 as the low potential coil 22.

In this embodiment, the penetration wiring 71 includes a first electrode layer 78, a second electrode layer 79, and a plurality of wiring plug electrodes 80. In the penetration wiring 71, each of the first electrode layer 78, the second electrode layer 79, and the wiring plug electrodes 80 is made of the same conductive material as the low potential coil 22 and the like. In other words, each of the first electrode layer 78, the second electrode layer 79, and the wiring plug electrodes 80 includes a barrier layer and a main body layer, similarly to the low potential coil 22 and the like.

The first electrode layer 78 forms the upper end of the penetration wiring 71. The second electrode layer 79 forms the lower end of the penetration wiring 71. The first electrode layer 78 is formed in an island shape and faces the low potential terminal 11 (first low potential terminal 11A) in the normal direction Z. The second electrode layer 79 is formed in an island shape and faces the first electrode layer 78 in the normal direction Z.

Each of the plurality of wiring plug electrodes 80 is embedded in the plurality of interlayer insulating layers 57 located in a region between the first electrode layer 78 and the second electrode layer 79. The plurality of wiring plug electrodes 80 are stacked from the lowermost insulating layer 55 toward the uppermost insulating layer 56 so as to be electrically connected to each other, and to electrically connect the first electrode layer 78 and the second electrode layer 79. Each of the plurality of wiring plug electrodes 80 has a plan-view area less than a plan-view area of the first electrode layer 78 and a plan-view area of the second electrode layer 79.

The number of layers stacked for the plurality of wiring plug electrodes 80 matches the number of layers stacked for the plurality of interlayer insulating layers 57. In this embodiment, six wiring plug electrodes 80 are embedded in each interlayer insulating layer 57, but the number of wiring plug electrodes 80 embedded in each interlayer insulating layer 57 is arbitrary. Of course, one or more wiring plug electrodes 80 penetrating the plurality of interlayer insulating layers 57 may be formed.

The low potential connection wiring 72 is formed in the first inner region 66 of the first transformer 21A (low potential coil 22) in the same interlayer insulating layer 57 as the low potential coil 22. The low potential connection wiring 72 is formed in an island shape and faces the high potential terminal 12 (first high potential terminal 12A) in the normal direction Z. It is preferable that the low potential connection wiring 72 has a plan-view area larger than the plan-view area of the wiring plug electrode 80. The low potential connection wiring 72 is electrically connected to the first inner end 24 of the low potential coil 22.

The lead-out wiring 73 is formed in the interlayer insulating layer 57 in a region between the semiconductor chip 41 and the penetration wiring 71. In this embodiment, the lead-out wiring 73 is formed in the first interlayer insulating layer 57 counting from the lowermost insulating layer 55. The lead-out wiring 73 includes a first end on one side, a second end on the other side, and a wiring portion connecting the first end and the second end. The first end of the lead-out wiring 73 is located in a region between the semiconductor chip 41 and the lower end of the penetration wiring 71. The second end of the lead-out wiring 73 is located in a region between the semiconductor chip 41 and the low potential connection wiring 72. The wiring portion extends along the first main surface 42 of the semiconductor chip 41 and extends in a strip shape in a region between the first end and the second end.

The first connection plug electrode 74 is formed in the interlayer insulating layer 57 in a region between the penetration wiring 71 and the lead-out wiring 73, and is electrically connected to the penetration wiring 71 and the first end of the lead-out wiring 73. The second connection plug electrode 75 is formed in the interlayer insulating layer 57 in a region between the low potential connection wiring 72 and the lead-out wiring 73, and is electrically connected to the low potential connection wiring 72 and the second end of the lead-out wiring 73.

The pad plug electrodes 76 are formed in the uppermost insulating layer 56 in a region between the low potential terminal 11 (first low potential terminal 11A) and the penetration wiring 71, and are electrically connected to the low potential terminal 11 and the upper end of the penetration wiring 71. The substrate plug electrodes 77 are formed in the lowermost insulating layer 55 in a region between the semiconductor chip 41 and the lead-out wiring 73. In this embodiment, the substrate plug electrodes 77 are formed in a region between the semiconductor chip 41 and the first end of the lead-out wiring 73, and are electrically connected to each of the semiconductor chip 41 and the first end of the lead-out wiring 73.

Referring to FIGS. 6 and 7, the plurality of first high potential wirings 33 are electrically connected to the corresponding high potential terminals 12A to 12D and the second inner ends 27 of the corresponding transformers 21A to 21D (high potential coils 23), respectively. The plurality of first high potential wirings 33 include the same structure. In the following, the structure of the first high potential wiring 33 connected to the first high potential terminal 12A and the first transformer 21A is described as an example. The description of the structures of the other first high potential wirings 33 are omitted since the description of the structure of the first high potential wiring 33 connected to the first transformer 21A applies mutatis mutandis.

The first high potential wiring 33 includes a high potential connection wiring 81 and one or more (a plurality in this embodiment) pad plug electrodes 82. The high potential connection wiring 81 and the pad plug electrodes 82 are preferably made of the same conductive material as the low potential coil 22 and the like. In other words, each of the high potential connection wiring 81 and the pad plug electrodes 82 preferably includes a barrier layer and a main body layer, similarly to the low potential coil 22 and the like.

The high potential connection wiring 81 is formed in the second inner region 67 of the high potential coil 23 in the same interlayer insulating layer 57 as the high potential coil 23. The high potential connection wiring 81 is formed in an island shape and faces the high potential terminal 12 (first high potential terminal 12A) in the normal direction Z. The high potential connection wiring 81 is electrically connected to the second inner end 27 of the high potential coil 23. The high potential connection wiring 81 is formed at a distance from the low potential connection wiring 72 in a plan view and does not face the low potential connection wiring 72 in the normal direction Z. This increases an insulation distance between the low potential connection wiring 72 and the high potential connection wiring 81, and increases a dielectric withstand voltage of the insulating layer 51.

The plurality of pad plug electrodes 82 are formed in the uppermost insulating layer 56 in a region between the high potential terminal 12 (first high potential terminal 12A) and the high potential connection wiring 81, and are electrically connected to the high potential terminal 12 and the high potential connection wiring 81, respectively. Each of the plurality of pad plug electrodes 82 has a plan-view area smaller than a plan-view area of the high potential connection wiring 81 in a plan view.

Referring to FIG. 7, a distance DI between the low potential terminal 11 and the high potential terminal 12 is preferably greater than a distance D2 between the low potential coil 22 and the high potential coil 23 (D2<D1). The distance D1 is preferably greater than the total thickness DT of the plurality of interlayer insulating layers 57 (DT<D1). A ratio D2/D1 of the distance D2 to the distance D1 may be 0.01 or more and 0.1 or less. The distance D1 is preferably 100 μm or more and 500 μm or less. The distance D2 may be 1 μm or more and 50 μm or less. The distance D2 is preferably 5 μm or more and 25 μm or less. Values of the distance D1 and the distance D2 are arbitrary and are appropriately adjusted according to a dielectric withstand voltage to be realized.

Referring to FIGS. 6 and 7, the semiconductor device 5 includes a dummy pattern 85 embedded in the insulating layer 51 so as to be located around the transformers 21A to 21D in a plan view.

The dummy pattern 85 is formed in a pattern (discontinuous pattern) different from the high potential coil 23 and the low potential coil 22, and is independent of the transformers 21A to 21D. In other words, the dummy pattern 85 does not function as the transformers 21A to 21D. The dummy pattern 85 is formed as a shield conductor layer that shields an electric field between the low potential coil 22 and the high potential coil 23 in the transformers 21A to 21D and suppresses electric field concentration on the high potential coil 23. In this embodiment, the dummy pattern 85 is routed with a line density equal to a line density of the high potential coil 23 per unit area. The line density of the dummy pattern 85 being equal to the line density of the high potential coil 23 means that the line density of the dummy pattern 85 falls within a range of ±20% of the line density of the high potential coil 23.

A depth position of the dummy pattern 85 inside the insulating layer 51 is arbitrary and is adjusted according to an electric field intensity to be mitigated. The dummy pattern 85 is preferably formed in a region closer to the high potential coil 23 than the low potential coil 22 in the normal direction Z. The dummy pattern 85 being closer to the high potential coil 23 in the normal direction Z means that a distance between the dummy pattern 85 and the high potential coil 23 in the normal direction Z is less than a distance between the dummy pattern 85 and the low potential coil 22.

In this case, it is possible to appropriately suppress electric field concentration on the high potential coil 23. The smaller the distance between the dummy pattern 85 and the high potential coil 23 in the normal direction Z, the more the electric field concentration on the high potential coil 23 may be suppressed. The dummy pattern 85 is preferably formed in the same interlayer insulating layer 57 as the high potential coil 23. In this case, the electric field concentration on the high potential coil 23 may be further appropriately suppressed. The dummy pattern 85 includes a plurality of dummy patterns having different electrical states. The dummy pattern 85 may include a high potential dummy pattern.

A depth position of a high potential dummy pattern 86 inside the insulating layer 51 is arbitrary and is adjusted according to the electric field intensity to be mitigated. The high potential dummy pattern 86 is preferably formed in a region closer to the high potential coil 23 than the low potential coil 22 in the normal direction Z. The high potential dummy pattern 86 being closer to the high potential coil 23 in the normal direction Z means that a distance between the high potential dummy pattern 86 and the high potential coil 23 in the normal direction Z is less than a distance between the high potential dummy pattern 86 and the low potential coil 22.

The dummy pattern 85 includes a floating dummy pattern formed in an electrically floating state within the insulating layer 51 so as to be positioned around the transformers 21A to 21D.

In this embodiment, the floating dummy pattern is laid out in dense lines so as to partially cover and partially expose a region around the high potential coil 23 in a plan view. The floating dummy pattern may be formed to have ends or to have no ends.

A depth position of the floating dummy pattern within the insulating layer 51 is arbitrary and is adjusted according to the electric field intensity to be mitigated.

The number of floating lines is arbitrary and is adjusted according to the electric field to be mitigated. The floating dummy pattern may be composed of a plurality of floating lines.

Referring to FIG. 7, the semiconductor device 5 includes a second functional device 60 formed at the first main surface 42 of the semiconductor chip 41 in a device region 62. The second functional device 60 is formed by utilizing a surface layer portion of the first main surface 42 of the semiconductor chip 41 and/or a region above the first main surface 42 of the semiconductor chip 41, and is covered by the insulating layer 51 (lowermost insulating layer 55). In FIG. 7, the second functional device 60 is shown in a simplified manner by a dashed line shown on the surface layer portion of the first main surface 42.

The second functional device 60 is electrically connected to the low potential terminal 11 via a low potential wiring, and is electrically connected to the high potential terminal 12 via a high potential wiring. The low potential wiring includes the same structure as that of the first low potential wiring 31 (second low potential wiring 32), except that it is routed within the insulating layer 51 so as to be connected to the second functional device 60. The high potential wiring includes the same structure as that of the first high potential wiring 33 (second high potential wiring 34), except that it is routed within the insulating layer 51 so as to be connected to the second functional device 60. A detailed description of the low potential wiring and the high potential wiring related to the second functional device 60 is omitted.

The second functional device 60 may include at least one selected from the group of a passive device, a semiconductor rectifier device, and a semiconductor switching device. The second functional device 60 may include a circuit network in which any two or more of the passive device, the semiconductor rectifier device, and the semiconductor switching device are selectively combined. The circuit network may form a portion or the entirety of an integrated circuit.

The passive device may include a semiconductor passive device. The passive device may include either or both of a resistor and a capacitor. The semiconductor rectifier device may include at least one selected from the group of a pn junction diode, a PIN diode, a Zener diode, a Schottky barrier diode, and a fast recovery diode. The semiconductor switching device may include at least one selected from the group of a BJT [Bipolar Junction Transistor], a MISFET [Metal Insulator Semiconductor Field Effect Transistor], an IGBT [Insulated Gate Bipolar Junction Transistor], and a JFET [Junction Field Effect Transistor].

Referring to FIGS. 5 to 7, the semiconductor device 5 further includes a seal conductor 61 embedded in the insulating layer 51. The seal conductor 61 is embedded in the insulating layer 51 in a wall shape so as to be spaced apart from the insulating sidewalls 53A to 53D in a plan view, and divides the insulating layer 51 into the device region 62 and an outer region 63. The seal conductor 61 suppresses entry of moisture and cracks from the outer region 63 into the device region 62.

The device region 62 is a region including the first functional device 45 (the plurality of transformers 21), the second functional device 60, the plurality of low potential terminals 11, the plurality of high potential terminals 12, the first low potential wiring 31, the second low potential wiring 32, the first high potential wiring 33, the second high potential wiring 34, and the dummy pattern 85. The outer region 63 is a region outside the device region 62.

The seal conductor 61 is electrically isolated from the device region 62. Specifically, the seal conductor 61 is electrically isolated from the first functional device 45 (the plurality of transformers 21), the second functional device 60, the plurality of low potential terminals 11, the plurality of high potential terminals 12, the first low potential wiring 31, the second low potential wiring 32, the first high potential wiring 33, the second high potential wiring 34, and the dummy pattern 85. More specifically, the seal conductor 61 is fixed in an electrically floating state. The seal conductor 61 does not form a current path connected to the device region 62.

The seal conductor 61 is formed in a strip shape along the insulating sidewalls 53A to 53D in a plan view. In this embodiment, the seal conductor 61 is formed in a quadrangular ring shape (specifically, a rectangular ring shape) in a plan view. As a result, the seal conductor 61 defines a quadrangular (specifically, rectangular) device region 62 in a plan view. The seal conductor 61 also defines a quadrangular (specifically, rectangular) outer region 63 that surrounds the device region 62 in a plan view.

Specifically, the seal conductor 61 includes an upper end at a side of the insulating main surface 52, a lower end at a side of the semiconductor chip 41, and a wall extending between the upper end and the lower end in a wall shape. In this embodiment, the upper end of the seal conductor 61 is formed so as to be spaced apart from the insulating main surface 52 toward the semiconductor chip 41, and is located within the insulating layer 51. In this embodiment, the upper end of the seal conductor 61 is covered by the uppermost insulating layer 56. The upper end of the seal conductor 61 may be covered by one or more interlayer insulating layers 57. The upper end of the seal conductor 61 may be exposed from the uppermost insulating layer 56. The lower end of the seal conductor 61 is formed so as to be spaced apart from the semiconductor chip 41 toward the upper end.

Thus, in this embodiment, the seal conductor 61 is embedded in the insulating layer 51 so as to be located at the side of the semiconductor chip 41 with respect to the plurality of low potential terminals 11 and the plurality of high potential terminals 12. Further, the seal conductor 61 faces the first functional device 45 (the plurality of transformers 21), the first low potential wiring 31, the second low potential wiring 32, the first high potential wiring 33, the second high potential wiring 34, and the dummy pattern 85 in the insulating layer 51 in a direction parallel to the insulating main surface 52. The seal conductor 61, in the insulating layer 51, may face a portion of the second functional device 60 in the direction parallel to the insulating main surface 52.

The seal conductor 61 includes a plurality of seal plug conductors 64 and one or more (a plurality of in this embodiment) seal via conductors 65. The number of seal via conductors 65 is arbitrary. The uppermost seal plug conductor 64 among the plurality of seal plug conductors 64 forms the upper end of the seal conductor 61. Each of the plurality of seal via conductors 65 forms the lower end of the seal conductor 61. The seal plug conductor 64 and the seal via conductor 65 are preferably made of the same conductive material as the low potential coil 22. In other words, each of the seal plug conductor 64 and the seal via conductor 65 preferably includes a barrier layer and a main body layer, similarly to the low potential coil 22 and the like.

The plurality of seal plug conductors 64 are embedded in the plurality of interlayer insulating layers 57, respectively, and are formed in a quadrangular ring shape (specifically, a rectangular ring shape) that surrounds the device region 62 in a plan view. The seal plug conductors 64 are stacked from the lowermost insulating layer 55 to the uppermost insulating layer 56 so as to be connected to each other. The number of stacked layers of the plurality of seal plug conductors 64 is equal to the number of stacked layers of the plurality of interlayer insulating layers 57. Of course, one or more seal plug conductors 64 may be formed so as to penetrate the plurality of interlayer insulating layers 57.

As long as one annular seal conductor 61 is formed by an assembly of the plurality of seal plug conductors 64, it is not necessary for all of the plurality of seal plug conductors 64 to be formed in an annular shape. For example, at least one selected from the group of the plurality of seal plug conductors 64 may be formed to have ends. Further, at least one selected from the group of the plurality of seal plug conductors 64 may be divided into a plurality of strip-shaped portions having ends. However, in consideration of the risk of moisture and cracks entering the device region 62, the plurality of seal plug conductors 64 are preferably formed in an endless shape (annular shape).

The plurality of seal via conductors 65 are formed in the lowermost insulating layer 55 in a region between the semiconductor chip 41 and the seal plug conductor 64. The plurality of seal via conductors 65 are formed to be spaced apart from the semiconductor chip 41 and connected to the seal plug conductor 64. The plurality of seal via conductors 65 have a plan-view area less than a plan-view area of the seal plug conductor 64. When a single seal via conductor 65 is formed, the single seal via conductor 65 may have a plan-view area equal to or greater than the plan-view area of the seal plug conductor 64.

A width of the seal conductor 61 may be 0.1 μm or more and 10 μm or less. The width of the seal conductor 61 is preferably 1 μm or more and 5 μm or less. The width of the seal conductor 61 is defined by the width in a direction perpendicular to a direction in which the seal conductor 61 extends.

Referring to FIGS. 7 and 8, the semiconductor device 5 further includes an isolation structure 130 that is interposed between the semiconductor chip 41 and the seal conductor 61 to electrically isolate the seal conductor 61 from the semiconductor chip 41. The isolation structure 130 preferably includes an insulator. In this embodiment, the isolation structure 130 is composed of a field insulating film 131 formed at the first main surface 42 of the semiconductor chip 41.

The field insulating film 131 includes at least one selected from the group of an oxide film (silicon oxide film) and a nitride film (silicon nitride film). The field insulating film 131 is preferably formed of a LOCOS (local oxidation of silicon) film, which is an example of an oxide film formed by oxidation of the first main surface 42 of the semiconductor chip 41. A thickness of the field insulating film 131 is arbitrary as long as it is possible to insulate the semiconductor chip 41 and the seal conductor 61. The thickness of the field insulating film 131 may be 0.1 μm or more and 5 μm or less.

The isolation structure 130 is formed at the first main surface 42 of the semiconductor chip 41, and extends in a strip shape along the seal conductor 61 in a plan view. In this embodiment, the isolation structure 130 is formed in a quadrangular ring shape (specifically, a rectangular ring shape) in a plan view. The isolation structure 130 includes a connection portion 132 to which the lower end (seal via conductor 65) of the seal conductor 61 is connected. The connection portion 132 may form an anchor portion in which the lower end (seal via conductor 65) of the seal conductor 61 is embedded toward a side of the semiconductor chip 41. Of course, the connection portion 132 may be formed flush with a main surface of the isolation structure 130.

The isolation structure 130 includes an inner end 130A at a side of the device region 62, an outer end 130B at a side of the outer region 63, and a main body 130C between the inner end 130A and the outer end 130B. The inner end 130A defines a region (i.e., the device region 62) in which the second functional device 60 is formed in a plan view. The inner end 130A may be formed integrally with an insulating film (not shown) formed at the first main surface 42 of the semiconductor chip 41.

The outer end 130B is exposed from the chip sidewalls 44A to 44D of the semiconductor chip 41 and is continuous with the chip sidewalls 44A to 44D of the semiconductor chip 41. More specifically, the outer end 130B is formed flush with the chip sidewalls 44A to 44D of the semiconductor chip 41. The outer end 130B forms a flush ground surface between the chip sidewalls 44A to 44D of the semiconductor chip 41 and the insulating sidewalls 53A to 53D of the insulating layer 51. Of course, in other embodiments, the outer end 130B may be formed in the first main surface 42 so as to be spaced apart from the chip sidewalls 44A to 44D.

The main body 130C includes a flat surface extending substantially parallel to the first main surface 42 of the semiconductor chip 41. The main body 130C includes a connection portion 132 to which the lower end (seal via conductor 65) of the seal conductor 61 is connected. The connection portion 132 is formed in a portion of the main body 130C spaced apart from the inner end 130A and the outer end 130B. The isolation structure 130 may take various forms in addition to the field insulating film 131.

Referring to FIG. 7, the semiconductor device 5 further includes an inorganic insulating layer 140 formed over the insulating main surface 52 of the insulating layer 51 so as to cover the seal conductor 61. The inorganic insulating layer 140 may be referred to as a passivation layer. The inorganic insulating layer 140 protects the insulating layer 51 and the semiconductor chip 41 from above the insulating main surface 52.

In this embodiment, the inorganic insulating layer 140 includes a laminated structure including a first inorganic insulating layer 141 and a second inorganic insulating layer 142. The first inorganic insulating layer 141 may contain silicon oxide. The first inorganic insulating layer 141 preferably contains USG (undoped silicate glass), which is silicon oxide without added impurities. A thickness of the first inorganic insulating layer 141 may be 50 nm or more and 5,000 nm or less. The second inorganic insulating layer 142 may contain silicon nitride. A thickness of the second inorganic insulating layer 142 may be 500 nm or more and 5,000 nm or less. By increasing a total thickness of the inorganic insulating layer 140, it is possible to increase a dielectric withstand voltage on the high potential coil 23.

When the first inorganic insulating layer 141 is made of USG and the second inorganic insulating layer 142 is made of silicon nitride, a dielectric breakdown voltage (V/cm) of USG exceeds a dielectric breakdown voltage (V/cm) of silicon nitride. Therefore, when the inorganic insulating layer 140 is thickened, it is preferable that the first inorganic insulating layer 141 is thicker than the second inorganic insulating layer 142.

The first inorganic insulating layer 141 may contain at least one selected from the group of BPSG (boron doped phosphor silicate glass) and PSG (phosphorus silicate glass), which are examples of silicon oxide. However, in this case, impurities (boron or phosphorus) are contained in the silicon oxide, and it is particularly preferable to form the first inorganic insulating layer 141 made of USG in order to increase the dielectric withstand voltage on the high potential coil 23. Of course, the inorganic insulating layer 140 may include a single-layer structure made of either the first inorganic insulating layer 141 or the second inorganic insulating layer 142.

The inorganic insulating layer 140 covers an entire region of the seal conductor 61, and includes a plurality of low potential pad openings 143 and a plurality of high potential pad openings 144 formed in a region outside the seal conductor 61. The plurality of low potential pad openings 143 expose the plurality of low potential terminals 11, respectively. The plurality of high potential pad openings 144 expose the plurality of high potential terminals 12, respectively. The inorganic insulating layer 140 may include an overlapping portion that rides up onto a peripheral portion of the low potential terminal 11. The inorganic insulating layer 140 may include an overlapping portion that rides up onto a peripheral portion of the high potential terminal 12.

The semiconductor device 5 further includes an organic insulating layer 145 formed over the inorganic insulating layer 140. The organic insulating layer 145 may contain a photosensitive resin. The organic insulating layer 145 may contain at least one selected from the group of polyimide, polyamide, and polybenzoxazole. In this embodiment, the organic insulating layer 145 contains polyimide. A thickness of the organic insulating layer 145 may be 1 μm or more and 50 μm or less.

The thickness of the organic insulating layer 145 is preferably greater than the total thickness of the inorganic insulating layer 140. Further, a total thickness of the inorganic insulating layer 140 and the organic insulating layer 145 is preferably equal to or greater than the distance D2 between the low potential coil 22 and the high potential coil 23. In this case, the total thickness of the inorganic insulating layer 140 is preferably 2 μm or more and 10 μm or less. Furthermore, the thickness of the organic insulating layer 145 is preferably 5 μm or more and 50 μm or less. According to these structures, the thicknesses of the inorganic insulating layer 140 and the organic insulating layer 145 may be reduced, and the dielectric withstand voltage on the high potential coil 23 may be appropriately increased by a laminated film of the inorganic insulating layer 140 and the organic insulating layer 145.

The organic insulating layer 145 includes a first portion 146 covering a region at a side of the low potential and a second portion 147 covering a region at a side of the high potential. The first portion 146 covers the seal conductor 61 with the inorganic insulating layer 140 sandwiched therebetween. The first portion 146 includes a plurality of low potential terminal openings 148 that expose the plurality of low potential terminals 11 (low potential pad openings 143) in the region outside the seal conductor 61. The first portion 146 may include an overlapping portion that rides up onto a periphery (overlapped portion) of the low potential pad opening 143.

The second portion 147 is formed at a distance from the first portion 146, and exposes the inorganic insulating layer 140 between the second portion 147 and the first portion 146. The second portion 147 includes a plurality of high potential terminal openings 149 that expose the plurality of high potential terminals 12 (high potential pad openings 144), respectively. The second portion 147 may include an overlapping portion that rides up onto a periphery (overlapped portion) of the high potential pad opening 144.

The second portion 147 collectively covers the transformers 21A to 21D and the dummy pattern 85. Specifically, the second portion 147 collectively covers the plurality of high potential coils 23, the plurality of high potential terminals 12, a first high potential dummy pattern 87, a second high potential dummy pattern 88, and a floating dummy pattern 121.

The embodiment of the present disclosure may be implemented in other forms. In the above-described embodiment, there has been described an example in which the first functional device 45 and the second functional device 60 are formed. However, a form including only the second functional device 60 without the first functional device 45 may be adopted. In this case, the dummy pattern 85 may be removed. According to this structure, the second functional device 60 may achieve the same effects as those described in the first embodiment (excluding the effects related to the dummy pattern 85).

That is, when a voltage is applied to the second functional device 60 via the low potential terminal 11 and the high potential terminal 12, it is possible to suppress undesired conduction between the high potential terminal 12 and the seal conductor 61. Further, when a voltage is applied to the second functional device 60 via the low potential terminal 11 and the high potential terminal 12, it is possible to suppress undesired conduction between the low potential terminal 11 and the seal conductor 61.

In the above-described embodiment, there has been described an example in which the second functional device 60 is formed. However, the second functional device 60 is not necessarily required, and may be removed.

In the above-described embodiment, there has been described an example in which the dummy pattern 85 is formed. However, the dummy pattern 85 is not necessarily required, and may be removed.

In the above-described embodiment, there has been described an example in which the first functional device 45 is a multi-channel type device including the plurality of transformers 21. However, the first functional device 45 that is a single-channel type device including a single transformer 21 may be employed.

### Transformer Arrangement

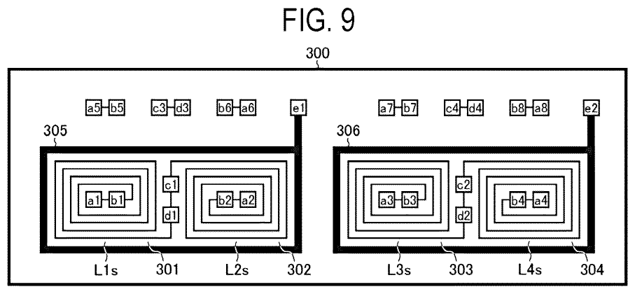

FIG. 9 is a plan view (top view) that schematically shows an example of a transformer arrangement in a two-channel transformer chip 300 (corresponding to the semiconductor device 5 described above). The transformer chip 300 in this figure includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one end of a secondary coil L1s forming the first transformer 301, and the pads c1 and d1 are connected to the other end of the secondary coil L1s. The pads a2 and b2 are connected to one end of a secondary coil L2s forming the second transformer 302, and the pads c1 and d1 are connected to the other end of the secondary coil L2s.

Further, the pads a3 and b3 are connected to one end of a secondary coil L3s forming the third transformer 303, and the pads c2 and d2 are connected to the other end of the secondary coil L3s. The pads a4 and b4 are connected to one end of a secondary coil L4s forming the fourth transformer 304, and the pads c2 and d2 are connected to the other end of the secondary coil L4s.

A primary coil forming the first transformer 301, a primary coil forming the second transformer 302, a primary coil forming the third transformer 303, and a primary coil forming the fourth transformer 304 are not shown in the figure. However, the primary coils basically include the same configuration as the secondary coils L1s to L4s, and are disposed directly below the secondary coils L1s to L4s, respectively, in such a manner as to face the secondary coils L1s to L4s.

That is, the pads a5 and b5 are connected to one end of the primary coil forming the first transformer 301, and the pads c3 and d3 are connected to the other end of the primary coil. Further, the pads a6 and b6 are connected to one end of the primary coil forming the second transformer 302, and the pads c3 and d3 are connected to the other end of the primary coil.

In addition, the pads a7 and b7 are connected to one end of the primary coil forming the third transformer 303, and the pads c4 and d4 are connected to the other end of the primary coil. Further, the pads a8 and b8 are connected to one end of the primary coil forming the fourth transformer 304, and the pads c4 and d4 are connected to the other end of the primary coil.

However, the pads a5 to a8, the pads b5 to b8, the pads c3 and c4, and the pads d3 and d4 are led out from an inside of the transformer chip 300 to the surface thereof through vias (not shown).

Among the plurality of pads, the pads a1 to a8 correspond to first current supply pads, the pads b1 to b8 correspond to first voltage measurement pads, the pads c1 to c4 correspond to second current supply pads, and the pads d1 to d4 correspond to second voltage measurement pads.

Therefore, with the transformer chip 300 of this configuration example, a series resistance component of each coil may be accurately measured during an inspection for defective products. Accordingly, it is possible to not only reject defective products in which each coil has a break in the wire thereof, but also to appropriately reject defective products in which each coil has an abnormal resistance value (e.g., a short circuit between coils), ultimately preventing defective products from being released into the market.

For the transformer chip 300 that has passed the defective product inspection, the above-mentioned pads may be used as a means for connecting a primary chip and a secondary chip (e.g., the above-mentioned controller chip 210 and driver chip 220).

Specifically, the pads a1 and b1, the pads a2 and b2, the pads a3 and b3, and the pads a4 and b4 may be connected to signal input or signal output terminals of the secondary chip, respectively, and the pads c1 and d1 and the pads c2 and d2 may be connected to common voltage application terminals (GND2) of the secondary chip, respectively.

On the other hand, the pads a5 and b5, the pads a6 and b6, the pads a7 and b7, and the pads a8 and b8 may be connected to signal input or signal output terminals of the primary chip, respectively, and the pads c3 and d3 and the pads c4 and d4 may be connected to common voltage application terminals (GND1) of the primary chip, respectively.

As shown in FIG. 9, the first transformer 301 to the fourth transformer 304 are arranged in a coupled state according to respective signal transmission directions. Referring to this figure, for example, the first transformer 301 and the second transformer 302 which transmit signals from the primary chip to the secondary chip are made into a first pair by the first guard ring 305. Further, for example, the third transformer 303 and the fourth transformer 304 which transmit signals from the secondary chip to the primary chip are made into a second pair by the second guard ring 306.

The reason for such coupling is to ensure a withstand voltage between the primary coil and the secondary coil when the primary coil and the secondary coil forming each of the first transformer 301 to the fourth transformer 304 are stacked in a vertical direction of the substrate of the transformer chip 300. However, the first guard ring 305 and the second guard ring 306 are not necessarily essential components.

The first guard ring 305 and the second guard ring 306 may be connected to a low impedance wiring such as a ground terminal via pads e1 and e2, respectively.

In the transformer chip 300, the pads c1 and d1 are shared by the secondary coil L1s and the secondary coil L2s. The pads c2 and d2 are shared by the secondary coil L3s and the secondary coil L4s. The pads c3 and d3 are shared by the primary coil L1p and the primary coil L2p. The pads c4 and d4 are shared by the corresponding primary coils. With this configuration, it is possible to reduce the number of pads and to reduce a size of the transformer chip 300.

Further, as shown in FIG. 9, the primary coil and the secondary coil forming each of the first transformer 301 to the fourth transformer 304 are desirably wound in a rectangular shape (or a track shape with rounded corners) in a plan view of the transformer chip 300. With this configuration, an area of an overlapping portion between the primary coil and the secondary coil becomes larger, and transmission efficiency of the transformer may be improved.

Of course, the transformer arrangement in this figure is merely one example, and the number, shape, and arrangement of the coils, as well as the arrangement of the pads, are arbitrary. In addition, the chip structure and transformer arrangement described so far may be applied to the entirety of a semiconductor device in which coils are integrated on a semiconductor chip.

### Signal Transmitter

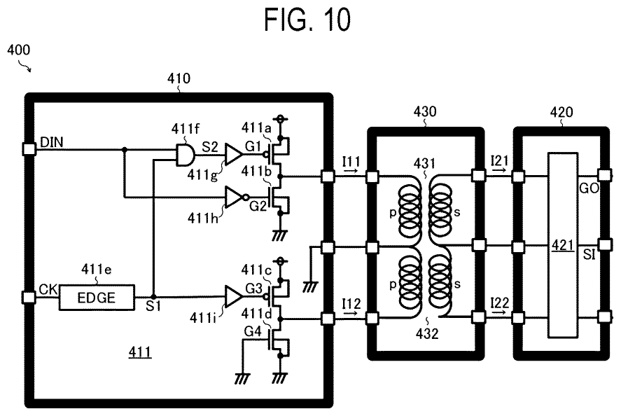

FIG. 10 is a diagram showing a configuration example of a signal transmitter 400. The signal transmitter 400 of this example configuration includes a first chip 410, a second chip 420, and a third chip 430. The first chip 410, the second chip 420, and the third chip 430 may be sealed in a single package. The signal transmitter 400 may be provided to the market as a semiconductor integrated circuit device (so-called insulated gate driver IC) formed by integrating the signal transmitter 400.

For example, a transmission circuit 411 is integrated on the first chip 410. The transmission circuit 411 generates pulse signals I11 and I12 according to a logic level of a control signal DIN input from an outside. For example, the transmission circuit 411 generates the pulse signal I11 when the control signal DIN is at a high level. The transmission circuit 411 generates the pulse signal I12 when the control signal DIN is at a low level. Each of the pulse signals I11 and I12 is pulse-driven in synchronization with a reference clock signal CK. The reference clock signal CK may be input from an outside of the signal transmitter 400 or may be generated inside the signal transmitter 400.

For example, a reception circuit 421 is integrated on the second chip 420. The reception circuit 421 outputs an output pulse signal GO in response to induced currents I21 and I22 input from the third chip 430 (details of which are described later).

For example, a plurality of transformers 431 and 432 are integrated on the third chip 430. The transformers 431 and 432 respectively correspond to insulating elements for transmitting the pulse signals I11 and I12 of the first chip 410 as pulse signals (induced currents I21 and I22) of the second chip 420 while electrically insulating between the transmission circuit 411 and the reception circuit 421.

Referring to the figure, the transformer 431 includes a primary coil 431p to which the pulse signal I11 is applied, and a secondary coil 431s which is electromagnetically coupled to the primary coil 431p to induce the induced current 121. The transformer 432 includes a primary coil 432p to which the pulse signal I12 is applied, and a secondary coil 432s which is electromagnetically coupled to the primary coil 432p to induce the induced current 122. Second terminals of the secondary coils 431s and 432s are both connected to a terminal for applying a reference voltage SI.

As the insulating element, a capacitor may be used instead of the transformer.

### Transmission Circuit

Referring next to FIG. 10, a configuration and an operation of the transmission circuit 411 are described. The transmission circuit 411 includes transistors 411a to 411d, an edge detection circuit 411e, an AND gate 411f, buffers 411g and 411i, and an inverter 411h. The transistors 411a and 411c may be P-channel types. The transistors 411b and 411d may be N-channel types.

A source and a back gate of the transistor 411a are connected to a power supply terminal. A source and a back gate of the transistor 411b are connected to a ground terminal. Drains of the transistors 411a and 411b are connected to a terminal for applying the pulse signal I11. A gate of the transistor 411a is connected to a terminal for applying a gate signal G1. A gate of the transistor 411b is connected to a terminal for applying a gate signal G2. The transistors 411a and 411b connected in this manner function as a first half-bridge output terminal for outputting the pulse signal I11 in response to the gate signals G1 and G2.

A source and a back gate of the transistor 411c are connected to a power supply terminal. A source and a back gate of the transistor 411d are connected to a ground terminal. Drains of the transistors 411c and 411d are connected to a terminal for applying the pulse signal I12. A gate of the transistor 411c is connected to a terminal for applying a gate signal G3. A gate of the transistor 411d is connected to a terminal for applying a gate signal G4. The transistors 411c and 411d connected in this manner function as a second half-bridge output terminal for outputting the pulse signal I12 in response to the gate signals G3 and G4. The gate signal G4 may be fixed to a low level.

The edge detection circuit 411e detects a pulse edge (rising edge or falling edge) of the reference clock signal CK and outputs an edge detection signal S1. The edge detection signal S1 may be, for example, a pulse signal that falls from a high level to a low level for a predetermined period in synchronization with the rising edge of the reference clock signal CK.

The AND gate 411f outputs a logic product signal S2 of the control signal DIN and the edge detection signal S1. Therefore, the logic product signal S2 is at a low level when at least one selected from the group of the control signal DIN and the edge detection signal S1 is at a low level. Further, the logic product signal S2 is at a high level when both the control signal D2 and the edge detection signal S1 are at high levels.

The buffer 411g generates the gate signal G1 by buffering and amplifying the logic product signal S2 while maintaining its logic level. Therefore, the gate signal G1 is at a high level when the logic product signal S2 is at a high level. At this time, the transistor 411a is in an off state. Moreover, the gate signal G1 is at a low level when the logic product signal S2 is at a low level. At this time, the transistor 411a is in an on state.

The inverter 411h generates the gate signal G2 by inverting the logic level of the control signal DIN. Therefore, the gate signal G2 is at a low level when the control signal DIN is at a high level. At this time, the transistor 411b is in an off state. Further, the gate signal G2 is at a high level when the control signal DIN is at a low level. At this time, the transistor 411b is in an on state.

The buffer 411i generates the gate signal G3 by buffering and amplifying the edge detection signal S1 while maintaining its logical level. Therefore, the gate signal G3 is at a high level when the edge detection signal S1 is at a high level. At this time, the transistor 411c is in an off state. Further, the gate signal G3 is at a low level when the edge detection signal S1 is at a low level. At this time, the transistor 411c is in an on state.

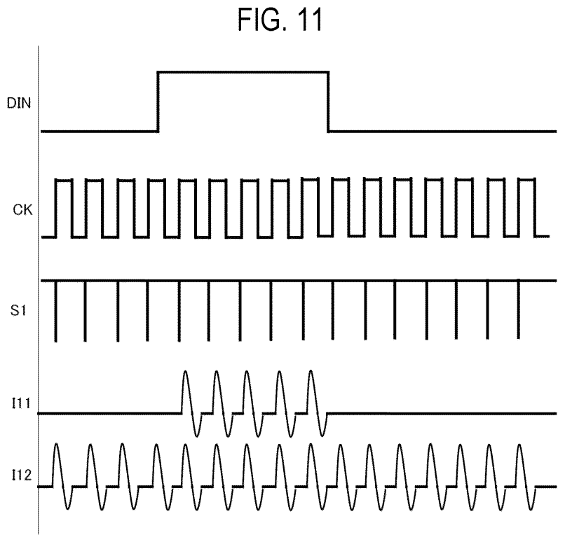

FIG. 11 is a diagram showing an example of a pulse generation operation in the transmission circuit 411. In this diagram, the control signal DIN, the reference clock signal CK, the edge detection signal S1, and the pulse signals I11 and I12 are depicted sequentially from the top.

As shown in the figure, during a high-level period of the control signal DIN, both of the pulse signals I11 and I12 are pulse-driven in synchronization with the reference clock signal CK. On the other hand, during a low-level period of the control signal DIN, only the pulse signal I12 is pulse-driven in synchronization with the reference clock signal CK.

### Reception Circuit

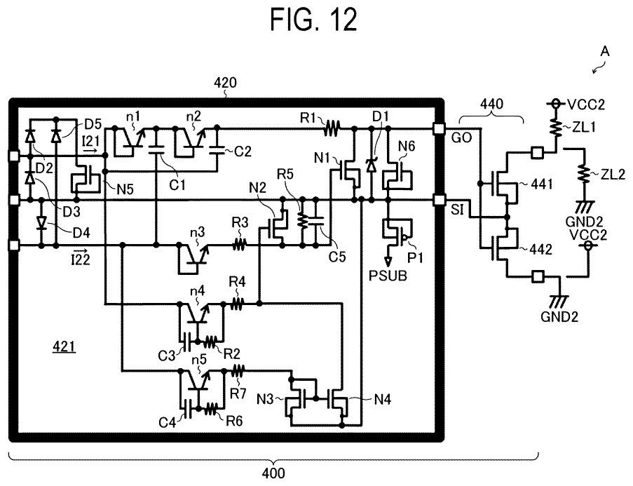

FIG. 12 is a diagram showing a configuration example of the reception circuit 421. The reception circuit 421 of this exemplary configuration includes, for example, transistors n1 to n5, transistors N1 to N6, a transistor P1, capacitors C1 to C5, resistors R1 to R7, and diodes D1 to D5. The transistors n1 to n5 may be of an npn type. The transistors N1 to N6 may be of an n-channel type. The transistor P1 may be of a p-channel type. The diode D1 may be a Zener diode.

A base and a collector of the transistor n1 are connected to a terminal for applying the induced current I21 (=a first end of the secondary coil 431s). An emitter of the transistor n1 and a base and a collector of the transistor n2 are both connected to a first end of the capacitor C1. A second end of capacitor C1 is connected to a terminal for applying the induced current 122 (=a first end of the secondary coil 432s). An emitter of the transistor n2 and a first end of the resistor R1 are both connected to a first end of the capacitor C2. A second end of the capacitor C2 is connected to the terminal for applying the induced current I21.

A second end of the resistor R1, a drain of the transistor N1, and a cathode of the diode D1 are all connected to a terminal for applying the output pulse signal GO. A source and a back gate of the transistor N1, and an anode of the diode D1 are all connected to a terminal for applying the reference voltage SI. The diode D1 corresponds to an electrostatic protection element.

A base and a collector of the transistor n3 are connected to the terminal for applying the induced current I22. An emitter of the transistor n3 is connected to a first terminal of the resistor R3. A second terminal of the resistor R3 is connected to a gate of the transistor N1.

A collector of the transistor n4 and a first end of the capacitor C3 are both connected to the terminal for applying the induced current I21. A base of the transistor n4 is connected to a second end of the capacitor C3 and a first end of the resistor R2. An emitter of the transistor n4 and a second end of the resistor R2 are both connected to a first end of the resistor R4. A second end of the resistor R4 is connected to a gate of the transistor N2. A source and a back gate of the transistor N2 are both connected to the terminal for applying the reference voltage SI. A drain of the transistor N2 is connected to the gate of the transistor N1.

First terminals of the resistor R5 and the capacitor C5 are both connected to the terminal for applying the reference voltage SI, and second terminals of the resistor R5 and the capacitor C5 are both connected to the gate of the transistor N1.

A collector of the transistor n5 and a first end of the capacitor C4 are both connected to the terminal for applying the induced current I22. A base of the transistor n5 is connected to a second end of the capacitor C4 and a first end of the resistor R6. An emitter of the transistor n5 and a second end of the resistor R6 are both connected to a first end of the resistor R7.

Gates of the transistors N3 and N4 are both connected to a drain of the transistor N3. The drain of the transistor N3 is connected to a second end of the resistor R7. A drain of the transistor N4 is connected to the gate of the transistor N2. Sources and back gates of the transistors N3 and N4 are both connected to the terminal for applying the reference voltage SI. The transistors N3 and N4 form a current mirror that replicates a drain current of the transistor N3 as a drain current of the transistor N4.

Cathodes of the diodes D2 and D5 are connected to a drain of the transistor N5. An anode of the diode D2 and a cathode of the diode D3 are both connected to the terminal for applying the induced current I21. Anodes of the diodes D3 and D4 and a source, a gate, and a back gate of the transistor N5 are all connected to the terminal for applying the reference voltage SI. A cathode of the diode D4 and an anode of the diode D5 are all connected to the terminal for applying the induced current I22. The diodes D2 to D5 and the transistor N5 correspond to electrostatic protection elements.

A drain of the transistor N6 is connected to the terminal for applying the output pulse signal GO. A source, a gate, and a back gate of the transistor N6 are all connected to the terminal for applying the reference voltage SI. A drain of the transistor P1 is connected to a terminal for applying a substrate voltage PSUB. A source, a gate, and a back gate of the transistor P1 are all connected to the terminal for applying the reference voltage SI. The transistors N6 and P1 correspond to electrostatic protection elements.

The signal transmitter 400 is mounted on an electronic device A together with a switch circuit 440. The signal transmitter 400 and the switch circuit 440 may be sealed in a common package.

The switch circuit 440 includes transistors 441 and 442. The transistors 441 and 442 may both be N-channel transistors.

Sources and back gates of the transistors 441 and 442 are both connected to the terminal for applying the reference voltage SI. Gates of the transistors 441 and 442 are both connected to the terminal for applying the output pulse signal GO.

In a first connection mode, a drain of the transistor 441 may be connected to a terminal for applying a power supply voltage VCC2 via a load ZL1, and a drain of the transistor 442 may be connected to a terminal for applying a ground voltage GND2. In this case, the switch circuit 440 functions as a low-side switch.

In a second connection mode, the drain of the transistor 441 may be connected to the terminal for applying the ground voltage GND2 via a load ZL2, and the drain of the transistor 442 may be connected to the terminal for applying the power supply voltage VCC2. In this case, the switch circuit 440 functions as a high-side switch.

Next, a basic operation of the signal transmitter 400 is described. During the high-level period of the control signal DIN, pulse driving of each of the pulse signals I11 and I12 is initiated. Therefore, the induced currents I21 and I22 are generated in the second chip 420. This causes the output pulse signal GO to rise to a high level. As a result, each of the transistors 441 and 442 is turned on, and a drive current may be supplied to the load ZL1 (or load ZL2).

On the other hand, during the low level period of the control signal DIN, the pulse driving of the pulse signal I11 is stopped, while the pulse driving of the pulse signal I12 is continued. Therefore, the induced current I21 stops flowing, while the induced current I22 continues to flow. This causes the output pulse signal GO to fall to a low level. As a result, the transistors 441 and 442 are turned off, and no drive current is supplied to the load ZL1 (or load ZL2).

### Multi-Channel Drive

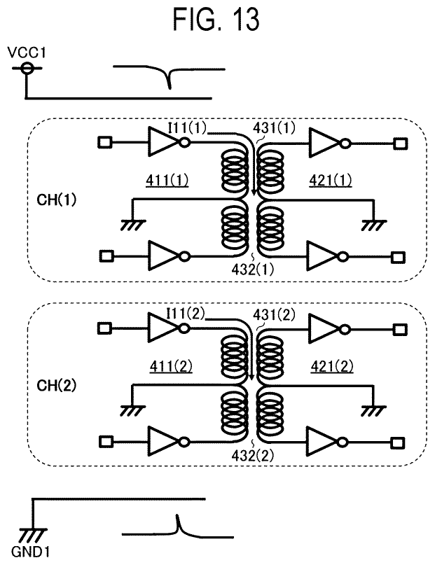

FIG. 13 is a diagram showing an example of multi-channel drive in the signal transmitter 400. The signal transmitter 400 shown in this figure includes the transmission circuit 411, the reception circuit 421, and the transformers 431 and 432, which are used for two channels. In this figure, each of the transmission circuit 411, the reception circuit 421, and the transformers 431 and 432 that make up a channel CH(1) has a “(1)” added to the end of their reference numerals. On the other hand, each of the transmission circuit 411, the reception circuit 421, and the transformers 431 and 432 that make up a channel CH(2) has a “(2)” added to the end of their reference numerals.

As mentioned above, in the insulated communication using the transformer (coil), a current pulse (=the above-mentioned pulse signal I11) is allowed to flow through the transformer (coil) to realize signal transmission from a primary side to a secondary side. A communication intensity at this time is determined by an amplitude of the current pulse. In other words, the larger the amplitude of the current pulse, the more stable the signal transmission from the primary side to the secondary side.

However, the current pulse causes an instantaneous drop in the power supply voltage VCC1. In particular, when communication timings in the channels CH(1) and CH(2) are close to each other, the amplitude of the current pulse decreases due to the drop in the power supply voltage VCC1, and the stability of signal transmission may be impaired.

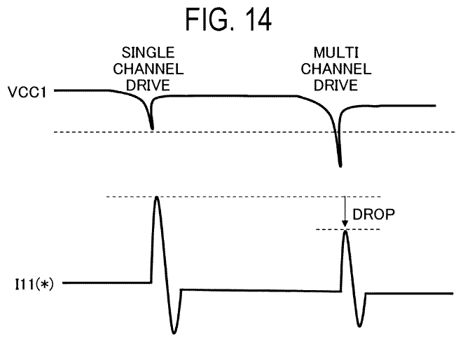

FIG. 14 is a diagram showing a state in which signals are attenuated during the multi-channel drive. The upper part depicts the power supply voltage VCC1. The lower part depicts the pulse signal I11(*) (where *=any one of 1, 2, . . . , n).

As shown in the figure, when multiple channels are driven simultaneously, the drop in the power supply voltage VCCI is larger than when a single channel is driven. In particular, the drop in the power supply voltage VCCI may grow larger as the number of channels driven simultaneously increases. In addition, if a timing of the drop in the power supply voltage VCC1 coincides with a timing of the insulated communication, an amplitude of the pulse signal I11(*) may decrease.

### Transmission Circuit (Comparative Example)

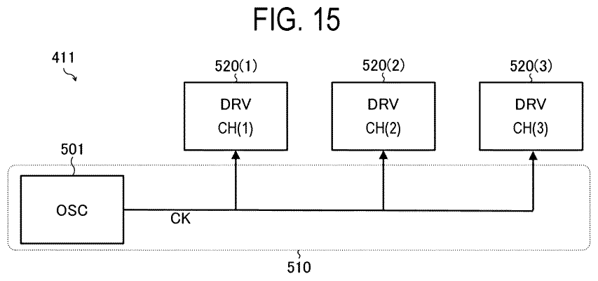

FIG. 15 is a diagram showing a comparative example of the transmission circuit 411 (=an example of a circuit configuration to be compared with the embodiment described later). The transmission circuit 411 of this comparative example includes an oscillator circuit 510 and driving circuits 520(1) to 520(3) of three channels. The number of channels may be two, or four or more.

The oscillator circuit 510 includes an oscillator 501. The oscillator 501 generates a reference clock signal CK.

Each of the driving circuits 520(1) to 520(3) drives a corresponding transformer (not shown) in synchronization with the reference clock signal CK common to all channels. The driving circuits 520(1) to 520(3) may be understood as functional blocks including the circuit elements 411a to 411i depicted in FIG. 10.

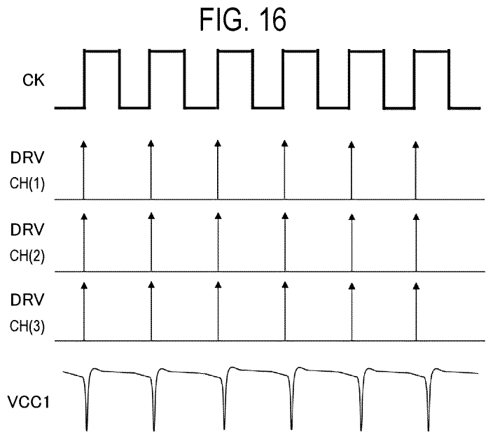

FIG. 16 is a diagram showing an example of a drive timing in this comparative example. In this figure, the reference clock signal CK, a drive timing of each of the driving circuits 520(1) to 520(3), and the power supply voltage VCCI are depicted sequentially from the top.

The drive timing of each of the driving circuits 520(1) to 520(3) is determined in synchronization with the common reference clock signal CK (rising edge in this figure). Therefore, the drive timing of each of the driving circuits 520(1) 520(3) overlaps among the channels. As a result, the drop in the power supply voltage VCCI becomes larger. The larger the drop in the power supply voltage VCC1, the easier it is for the amplitude of each of the pulse signals I11(1) to I11(3) to decrease, which may impair the stability of signal transmission.

In view of the above considerations, embodiments capable of performing stable signal transmission even during multi-channel drive are proposed below.

### Transmission Circuit (First Embodiment)

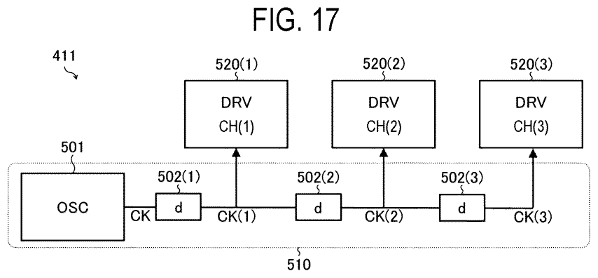

FIG. 17 is a diagram showing a transmission circuit 411 according to a first embodiment. The transmission circuit 411 of this embodiment is based on the comparative example (FIG. 15) described above, and is modified in the configuration of the oscillator circuit 510. Referring to this figure, the oscillator circuit 510 includes delay circuits 502(1) to 502(3) in addition to the oscillator 501 described above.

The delay circuits 502(1) to 502(3) are connected in series to an output terminal of the oscillator 501, i.e., a terminal for applying the reference clock signal CK.

The reference clock signal CK is input from the oscillator 501 to the delay circuit 502(1) provided at a first stage on a side that is most upstream. The delay circuit 502(1) delays the reference clock signal CK to generate a clock signal CK(1). The clock signal CK(1) is output to the driving circuit 520(1). The driving circuit 520(1) drives a transformer (not shown) of the channel CH(1) in synchronization with the clock signal CK(1).

The delay circuit 502(2) provided at a second stage receives the clock signal CK(1) from the delay circuit 502(1). The delay circuit 502(2) delays the clock signal CK(1) to generate a clock signal CK(2). The clock signal CK(2) is output to the driving circuit 520(2). The driving circuit 520(2) drives a transformer (not shown) of the channel CH(2) in synchronization with the clock signal CK(2).

The clock signal CK(2) is input from the delay circuit 502(2) to the delay circuit 502(3) provided at a third stage on a side that is most downstream. The delay circuit 502(3) delays the clock signal CK(2) to generate a clock signal CK(3). The clock signal CK(3) is output to the driving circuit 520(3). The driving circuit 520(3) drives a transformer (not shown) of the channel CH(3) in synchronization with the clock signal CK(3).

In this manner, the oscillator circuit 510 generates the clock signals CK(1) to CK(3) having different phases by using the delay circuits 502(1) to 502(3).

The driving circuits 520(1) to 520(3) drive the corresponding transformers (not shown) in synchronization with the clock signals CK(1) to CK(3), respectively. As described above, each of the driving circuits 520(1) to 520(3) may be understood as a functional block including the circuit elements 411a to 411i depicted in FIG. 10.

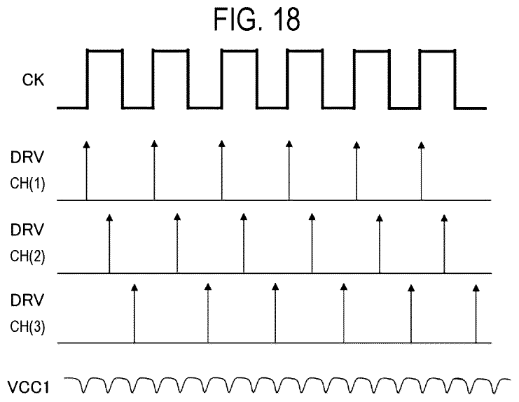

FIG. 18 is a diagram showing an example of a drive timing in the first embodiment. In this figure similar to FIG. 16, the reference clock signal CK, a drive timing of each of the driving circuits 520(1) to 520(3), and the power supply voltage VCC1 are depicted sequentially from the top.

The drive timing of each of the driving circuits 520(1) to 520(3) is determined in synchronization with the clock signals CK(1) to CK(3) having different phases. Therefore, the drive timing of each of the driving circuits 520(1) 520(3) is shifted between channels. As a result, the drop of the power supply voltage VCC1 is reduced. The smaller the drop of the power supply voltage VCC1, the less likely it is for an amplitude of each of the pulse signals I11(1) to I11(3) to decrease, thereby improving the stability of signal transmission.

### Transmission Circuit (Second Embodiment)

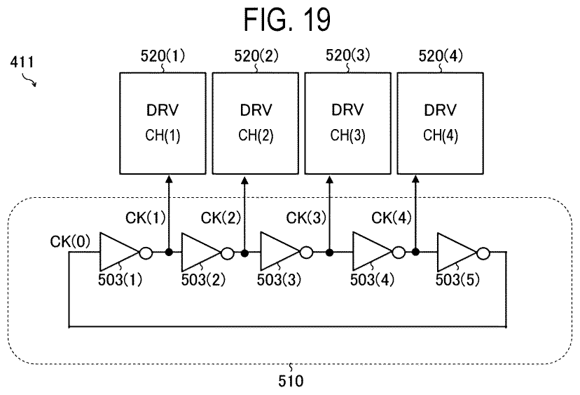

FIG. 19 is a diagram showing a transmission circuit 411 according to a second embodiment. The transmission circuit 411 of this embodiment includes an oscillator circuit 510 and four channel driving circuits 520(1) to 520(4). The number of channels may be two or three, or may be five or more.

The oscillator circuit 510 includes inverters 503(1) to 503(5). An input terminal of the inverter 503(1) and an output terminal of the inverter 503(5) are both connected to a terminal for applying a clock signal CK(0). An output terminal of the inverter 503(1) and an input terminal of the inverter 503(2) are both connected to a terminal for applying a clock signal CK(1). An output terminal of the inverter 503(2) and an input terminal of the inverter 503(3) are both connected to a terminal for applying a clock signal CK(2). An output terminal of the inverter 503(3) and an input terminal of the inverter 503(4) are both connected to a terminal for applying the clock signal CK(3). An output terminal of the inverter 503(4) and an input terminal of the inverter 503(5) are both connected to a terminal for applying a clock signal CK(4).

The inverter 503(1) inverts a logic level of the clock signal CK(0) to generate the clock signal CK(1). Therefore, when the clock signal CK(0) rises from a low level to a high level, the clock signal CK(1) falls from a high level to a low level. Conversely, when the clock signal CK(0) falls from a high level to a low level, the clock signal CK(1) rises from a low level to a high level. Rising/falling timings of the clock signal CK(1) lag behind falling/rising timings of the clock signal CK(0). Therefore, the inverter 503(1) also functions as a delay circuit that gives a delay to the clock signal CK(0) to generate the clock signal CK(1).

Similarly, the inverter 503(2) inverts a logic level of the clock signal CK(1) and gives a delay to generate the clock signal CK(2). The inverter 503(3) inverts a logic level of the clock signal CK(2) and gives a delay to generate the clock signal CK(3). The inverter 503(4) inverts a logic level of the clock signal CK(3) and gives a delay to generate the clock signal CK(4). The inverter 503(5) inverts a logic level of the clock signal CK(4) and gives a delay to generate the clock signal CK(0).

In this way, the oscillator circuit 510 may be understood as a ring oscillator including the inverters 503(1) to 503(5) connected in a ring shape. The oscillator circuit 510 outputs the clock signals CK(1) to CK(4) having different phases from the output terminals of the inverters 503(1) to 503(4), i.e., from intermediate nodes of the ring oscillator.

The driving circuits 520(1) 520(4) drive corresponding transformers (not shown) in synchronization with the clock signals CK(1) to CK(4), respectively. Further, as described above, the driving circuits 520(1) 520(4) may be understood as functional blocks including the circuit elements 411a to 411i depicted in FIG. 10.

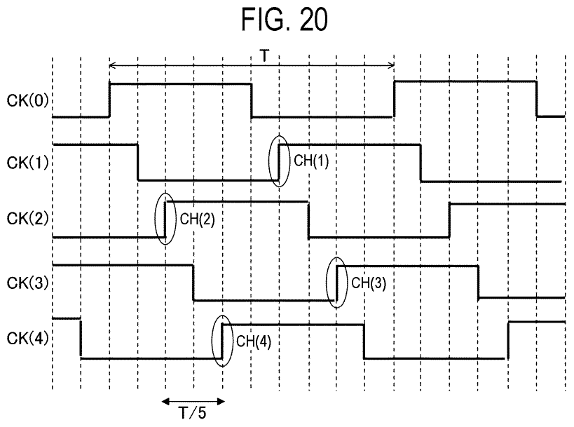

FIG. 20 is a diagram showing an example of a drive timing in the second embodiment. In this figure, the clock signals CK(1) to(4) are depicted sequentially from the top.

A drive timing of each of the driving circuits 520(1) 520(4) is determined in synchronization with one edge, for example, a rising edge, of each of the clock signals CK(1) to CK(4) having different phases. Therefore, the drive timing of each of the driving circuits 520(1) 520(4) is shifted between channels. The drive timing of each of the driving circuits 520(1) 520(4) may be determined in synchronization with a falling edge of each of the clock signals CK(1) to CK(4).

For example, a case is considered in which the oscillator circuit 510 includes five stages of inverters 503(1) to 503(5). In this case, the drive timing of each of the driving circuits 520(1) to 520(4) is shifted by a minimum of T/5, where T is a period of each of the clock signals CK(0) to CK(4). As a result, the drop in the power supply voltage VCC1 becomes smaller. The smaller the drop in the power supply voltage VCC1, the less likely it is for an amplitude of each of the pulse signals I11(1) to I11(4) to decrease, thereby improving the stability of signal transmission.

### Transmission Circuit (Third Embodiment)

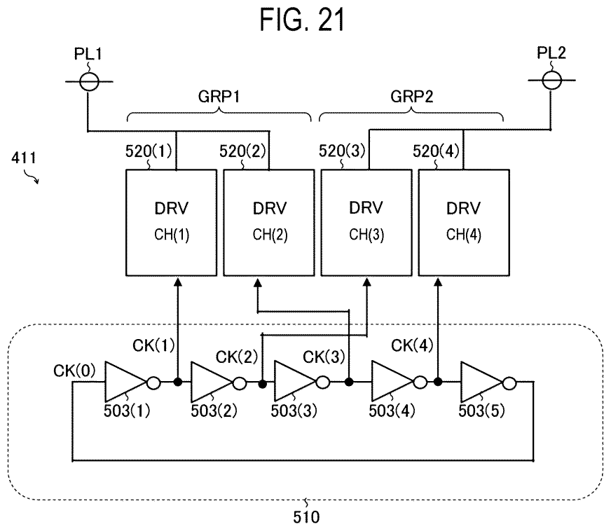

FIG. 21 is a diagram showing a transmission circuit 411 according to a third embodiment. The transmission circuit 411 of this embodiment is based on the second embodiment (FIG. 19) described above, but is modified in the drive timing of each of the driving circuits 520(1) to 520(4), power supply paths to the driving circuits 520(1) to 520(4), and the configuration of the oscillator circuit 510.

As a first modification, the drive timing of each of the driving circuits 520(1) to 520(4) is determined in synchronization with both edges, i.e., both the rising edge and the falling edge, of each of the clock signals CK(1) to CK(4) having different phases.

This configuration makes it possible to double the drive timing of each of the driving circuits 520(1) to 520(4) while maintaining an oscillation frequency f(=1/T) of each of the clock signals CK(0) to CK(4). In particular, this configuration is effective in applications where it is desired to increase a signal transmission speed, such as an insulated gate driver ICs.

However, if the above-mentioned modification is applied to the second embodiment (FIG. 19) without any research, the phase shift between the channels will be reduced to T/10. Therefore, if the oscillation frequency f of each of the clock signals CK(1) to CK(4) is high, there is a risk that the drive timings of the driving circuits 520(1) to 520(4) overlap.

Therefore, as a second modification, the driving circuits 520(1) to 520(4) are supplied with electric power from different power supply lines according to each of the multiple groups to which they belong. For example, the driving circuits 520(1) and 520(2) belonging to a group GRP1 are both supplied with electric power from the terminal for applying the power supply voltage VCC1 via a power supply line PL1. On the other hand, the driving circuits 520(3) and 520(4) belonging to a group GRP2 are both supplied with electric power from the terminal for applying the power supply voltage VCC1 via a power supply line PL2.

With this configuration, even if the drive timing of the driving circuits 520(1) and 520(2) belonging to the group GRP1 and the drive timing of the driving circuits 520(3) and 520(4) belonging to the group GRP2 are close to each other, the two groups are less likely to be affected by each other. Therefore, it is possible to suppress a drop in the power supply voltage VCC1.

In particular, in order to minimize the influence between channels, it is desirable to provide separate and independent power supply lines PL(1) to PL(4) for the driving circuits 520(1) to 520(4), respectively. However, if it is difficult to adopt such a configuration due to chip area restrictions or the like, a certain degree of effect may be obtained by dividing at least into two and just providing the power supply lines PL1 and PL2 as proposed in this embodiment.

It is also preferable that the power supply lines PL1 and PL2 are connected to separate power supply terminals. However, if it is difficult to adopt this configuration, the power supply lines PL1 and PL2 may be ultimately connected to a common power supply terminal.

In addition, the configuration in which the power supply lines are separated among multiple channels may be applied not only to the case in which the driving circuits 520(1) to 520(4) are synchronized with both edges of the clock signals CK(1) to CK(4), but also to the case in which they are synchronized with one edge.

Further, as a third modification accompanied by the provision of the two-split power supply lines PL1 and PL2, clock signals CK(i) and (i+1) output from adjacent inverters 503(i) and 503(i+1) (where i=1, 2, or 3) among the inverters 503(1) to 503(4) are output to the driving circuits belonging to different groups GRP1 or GRP2 among the driving circuits 520(1) to 520(4).

Referring to this figure, output destinations of the clock signals CK(1) to CK(4) are not assigned to the driving circuits 520(1) to 520(4) in the sequential order, but the order of the output destinations of the clock signals CK(2) and CK(3) is swapped. Specifically, the clock signal CK(2) is output to the driving circuit 520(3), and the clock signal CK(3) is output to the driving circuit 520(2).

Focusing on the inverters 503(1) and 503(2), the clock signal CK(1) is output to the driving circuit 520(1) belonging to the group GRP1. On the other hand, the clock signal CK(2) is output to the driving circuit 520(3) belonging to the group GRP2.

Focusing on the inverters 503(2) and 503(3), the clock signal CK(2) is output to the driving circuit 520(3) belonging to the group GRP2. On the other hand, the clock signal CK(3) is output to the driving circuit 520(2) belonging to the group GRP1.

Focusing on the inverters 503(3) and 503(4), the clock signal CK(3) is output to the driving circuit 520(2) belonging to the group GRP1. On the other hand, the clock signal CK(4) is output to the driving circuit 520(4) belonging to the group GRP2.

With this configuration, a phase difference may be applied to the drive timing between the driving circuits 520(1) and 520(2) belonging to the group GRP1, and also the drive timing between the driving circuits 520(3) and 520(4) belonging to the group GRP2.

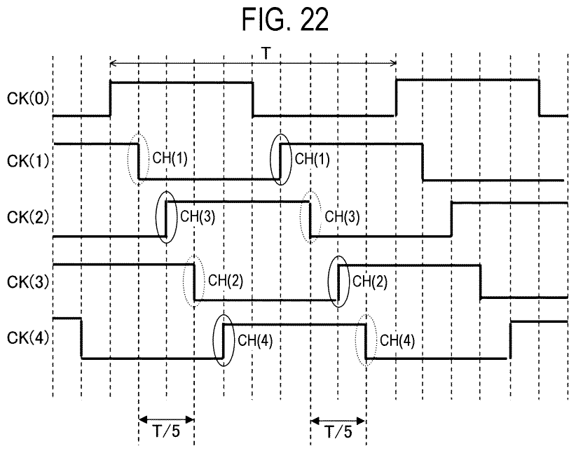

FIG. 22 is a diagram showing an example of a drive timing in the third embodiment. In this figure, similarly to FIG. 20, the clock signals CK(1) to CK(4) are depicted sequentially from the top.

As shown in the figure, the drive timing of each of the driving circuits 520(1) to 520(4) is determined in synchronization with both the rising edge and the falling edge of each of the clock signals CK(1) to CK(4).

As described above, the order of the output destinations of the clock signals CK(2) and CK(3) is swapped. Therefore, it is possible to ensure a phase difference of at least T/5 between the drive timings of the driving circuits 520(1) and 520(2) belonging to group GRP1 and between the drive timings of the driving circuits 520(3) and 520(4) belonging to group GRP2.

### Transmission Circuit (Fourth Embodiment)

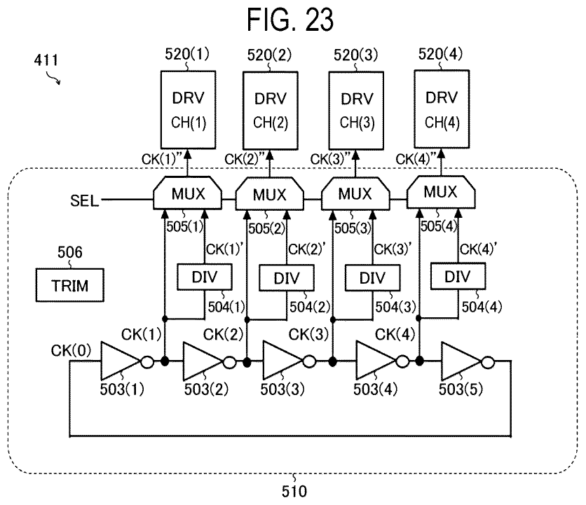

FIG. 23 is a diagram showing a transmission circuit 411 according to a fourth embodiment. The transmission circuit 411 of this embodiment is based on the second embodiment (FIG. 19) and further includes frequency divider circuits 504(1) to 504(4), multiplexers 505(1) to 505(4), and a trimming circuit 506.

The frequency divider circuits 504(1) to 504(4) divide frequencies of the clock signals CK(1) to CK(4), respectively, to generate frequency-divided clock signals CK(1)′ to CK(4)′.

The multiplexers 505(1) to 505(4) select one of the clock signals CK(1) to CK(4) and the divided clock signals CK(1)′ to CK(4)′ as selected clock signals CK(1)″ to CK(4)″ in response to a mode switching signal SEL, and output the selected clock signals CK(1)″ to CK(4)″ to the driving circuits 520(1) to 520(4), respectively. For example, when the mode switching signal SEL is at a high level (=a logic level in a high speed mode), the clock signals CK(1) to CK(4) are selected and output as the selected clock signals CK(1)″ to CK(4)″. On the other hand, when the mode switching signal SEL is at a low level (=a logic level in a low speed mode), the divided clock signals CK(1)′ to CK(4)′ are selected and output as the selected clock signals CK(1)″ to CK (4)″.

The mode switching signal SEL may be input from outside the signal transmitter 400, or may be read from a memory or a register built into the signal transmitter 400.

The driving circuits 520(1) to 520(4) drive the corresponding transformers (not shown) in synchronization with the selected clock signals CK(1)″ to CK(4)″ output from the multiplexers 505(1) to 505(4), respectively.

With this configuration, a drive frequency of each of the driving circuits 520(1) to 520(4) is arbitrarily switched by switching the logic level of the mode switching signal SEL.

Therefore, when high speed driving is not required, a phase difference between the channels may be increased by lowering the drive frequency of each of the driving circuits 520(1) to 520(4). In particular, this configuration is effective in applications where the required signal transmission speed varies greatly depending on specifications, such as an insulated gate driver IC.

The trimming circuit 506 adjusts the oscillation frequency f of each of the clock signals CK(0) to CK(4). For example, the trimming circuit 506 may adjust a drive current of each of the inverters 503(1) to 503(5). In this case, the more the drive current of each of the inverters 503(1) to 503(5) is increased, the higher the oscillation frequency f of each of the clock signals CK(0) to CK(4). Conversely, the more the drive current of each of the inverters 503(1) to 503(5) is decreased, the lower the oscillation frequency f of each of the clock signals CK(0) to CK(4). The trimming circuit 506 may be used to finely adjust the oscillation frequency f.

Further, the trimming circuit 506 may adjust the drive current of each of the inverters 503(1) to 503(5) so as to lower the oscillation frequency f of each of the clock signals CK(0) to CK(4) in a low speed mode (SEL=L) and to raise the oscillation frequency f of each of the clock signals CK(0) to CK(4) in a high speed mode (SEL=H). In that case, the previously mentioned frequency divider circuits 504(1) to 504(4) and multiplexers 505(1) to 505(4) may be omitted.

### Consideration Regarding High Speed Driving

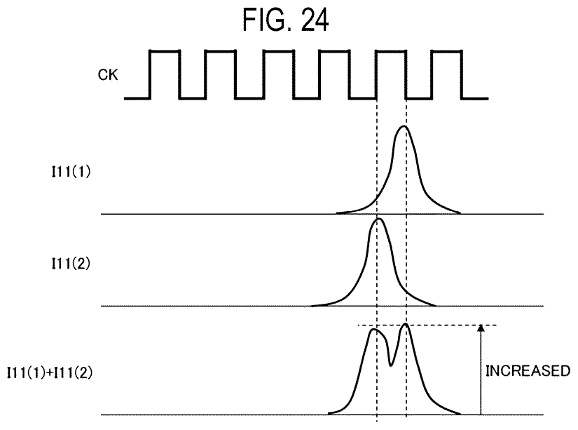

FIG. 24 shows a state in which the driving timings of the multiple channels overlap. In this figure, the reference clock signal CK, the pulse signals I11(1) and I11(2), and an added pulse signal I11(1)+I11(2) are depicted sequentially from the top. The added pulse signal I11(1)+I11(2) may be understood as a combined current flowing through the terminal for applying the power supply voltage VCC1. The reference clock signal CK may also be interpreted as the clock signals CK(1) to CK(n) mentioned above.

If the oscillation frequency f of the reference clock signal CK is increased to increase the signal transmission speed, on-times of the pulse signals I11(1) and I11(2) may overlap even when the drive timings of the multiple channels are shifted. Therefore, when the multiple channels are driven simultaneously, a peak value of the added pulse signal I11(1)+I11(2), i.e., the combined current flowing to the terminal for applying the power supply voltage VCC1, may increase compared to a case where a single channel is driven.

In general, the higher the temperature (junction temperature Tj or ambient temperature Ta) of the signal transmitter 400, the lower the current capability of the transistor 411a included in the transmission circuit 411. The lower the current capability of the transistor 411a, the duller the waveforms of the pulse signals I11(1) and I11(2) become. Therefore, at high temperatures, the overlap of the on-times described above tends to become large.

In view of the above considerations, the oscillator circuit 510 may be configured such that the oscillation frequency f of the reference clock signal CK or each of the clock signals CK(1) to CK(n) has a negative temperature characteristic.

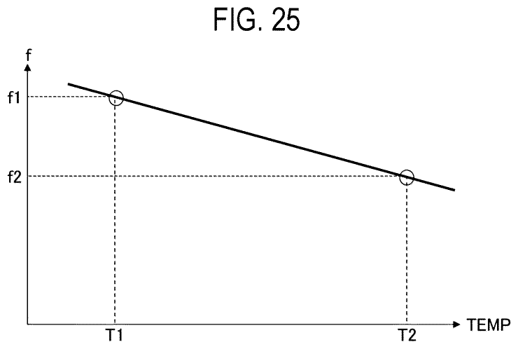

FIG. 25 is a diagram showing temperature dependency of the oscillation frequency f. As shown in this figure, the oscillation frequency f may be changed linearly according to the temperature TEMP such that the oscillation frequency f is f1 at a temperature T1 and is f2 (<f1) at a temperature T2 (>T1). That is, the oscillation frequency f may be lowered as the temperature TEMP increases. For example, a temperature coefficient of the oscillation frequency f may be −100 ppm/degrees C. or less.

In the previously described second embodiment (FIG. 19), third embodiment (FIG. 21), or fourth embodiment (FIG. 23), the drive current of each of the inverters 503(1) to 503(5) may be reduced as the temperature TEMP increases.

With this configuration, the on-times of the pulse signals I11(1) and I11(2) are unlikely to overlap even at high temperatures.

In addition, at high temperatures, an on-threshold voltage of the transistor generally decreases. Accordingly, a smaller pulse current is required to drive the reception circuit 421 than at low temperatures. Therefore, even if the oscillation frequency f is lowered at high temperatures, the application may be established without any problems.

### Combination of Embodiments

The embodiments proposed above may be combined arbitrarily as long as there are no contradictions. For example, the third embodiment (FIG. 21) is based on the second embodiment (FIG. 19), but the comparative example (FIG. 15), the first embodiment (FIG. 17), and the fourth embodiment (FIG. 23) may be applied as a basis for the configuration in which the power lines are separated among the multiple channels.

Further, for example, the aforementioned fourth embodiment (FIG. 23) is based on the second embodiment (FIG. 19), but a frequency divider circuit 504 and a multiplexer 505 may be introduced based on the first embodiment (FIG. 17) or the third embodiment (FIG. 21).

### Application to Vehicles

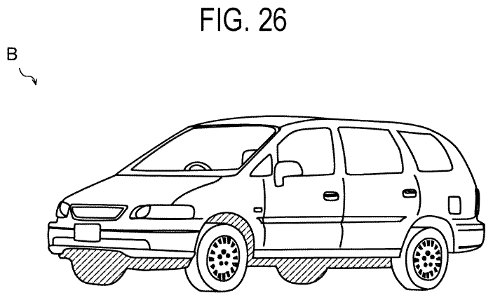

FIG. 26 shows an exterior of a vehicle. The vehicle B in this configuration example is equipped with various electronic devices that operate with electric power supplied from a battery.

The vehicle B includes not only engine vehicles but also electric vehicles (xEVs such as BEVs [battery electric vehicles], HEVs [hybrid electric vehicles], PHEVs/PHVs [plug-in hybrid electric vehicles/plug-in hybrid vehicles], or FCEVs/FCVs [fuel cell electric vehicles/fuel cell vehicles]).

The signal transmitters 200 and 400 described above may be incorporated into any of the electronic devices installed in the vehicle B.

### Supplementary Note

The signal transmitter according to the present disclosure is capable of stably transmitting multiple signals. The following supplementary notes are provided regarding the above-described disclosure.

### Supplementary Note 1

A signal transmitter (400), including:
a transmission circuit (411);
a reception circuit (421); and
a plurality of insulating elements (431(1) to 431(n)) configured to transmit a plurality of signals (I11(1) to I11(n) (where n is an integer of 2 or more), respectively, from the transmission circuit (411) to the reception circuit (421) while insulating between the transmission circuit (411) and the reception circuit (421),
wherein the transmission circuit (411) includes:
   an oscillator circuit (510) configured to generate a plurality of clock signals (CK(1) to CK(n)) having different phases; and
   a plurality of driving circuits (520(1) to 520(n)) configured to drive the plurality of insulating elements (431(1) to 431(n)) in synchronization with the plurality of clock signals (CK(1) to CK(n)), respectively.

### Supplementary Note 2

The signal transmitter (400) of Supplementary Note 1, wherein the oscillator circuit (510) includes:
an oscillator (501) configured to generate a reference clock signal (CK); and
a plurality of delay circuits (502(1) to 502(n)) connected in series,
wherein the reference clock signal (CK) is input to the delay circuit (502(1)) located most upstream among the plurality of delay circuits (502(1) to 502(n)), and the plurality of clock signals (CK(1) to CK(n)) are output from the plurality of delay circuits (502(1) to 502(n)), respectively.

### Supplementary Note 3

The signal transmitter (400) of Supplementary Note 1, wherein the oscillator circuit (510) is a ring oscillator including a plurality of inverters (503(1) to 503(n+1)) connected in a ring shape, and
wherein the plurality of clock signals (CK(1) to CK(n)) are output from the plurality of inverters (503(1) to (n)), respectively.

### Supplementary Note 4

The signal transmitter (400) of any one of Supplementary Notes 1 to 3, wherein the plurality of driving circuits (520(1) to 520(n)) are configured to drive the plurality of insulating elements (431(1) to 431(n)) in synchronization with both a rising edge and a falling edge of each of the plurality of clock signals (CK(1) to CK(n)).

### Supplementary Note 5

The signal transmitter (400) of any one of Supplementary Notes 1 to 4, wherein the plurality of driving circuits (520(1) to 520(n)) are supplied with electric power from different power supply lines (PL1 and PL2) for each of a plurality of groups (GRP1 and GRP2) to which the plurality of driving circuits (520(1) to 520(n)) respectively belong.

### Supplementary Note 6

The signal transmitter (400) of Supplementary Note 3, wherein the plurality of driving circuits (520(1) to 520(n)) are supplied with electric power from different power supply lines (PL1 and PL2) for each of a plurality of groups (GRP1 and GRP2) to which the plurality of driving circuits (520(1) to 520(n)) respectively belong, and wherein the clock signals (CK(i) and CK(i+1)) output from adjacent inverters (503(i) and 503(i+1) (where i=1, 2, . . . , or n−1)) among the plurality of inverters (503(1) to 503(n)) are output to driving circuits belonging to different groups (GRP1 and GRP2) among the plurality of driving circuits (520(1) to 520(n)).

### Supplementary Note 7

The signal transmitter (400) of any one of Supplementary Notes 1 to 6, further including:

a plurality of frequency divider circuits (504(1) to 504(n)) configured to divide frequencies of the plurality of clock signals (CK(1) to CK(n)), respectively, to generate a plurality of divided clock signals (CK(1)′ to CK(n)′); and a plurality of multiplexers (505(1) to 505(n)) configured to output one of the plurality of clock signals (CK(1) to CK(n)) and the plurality of divided clock signals (CK(1)′ to CK(n)′) to the plurality of driving circuits (520(1) to 520(n)), respectively, as a plurality of selected clock signals (CK(1)″ to CK(n)″), wherein the plurality of driving circuits (520(1) to 520(n)) are configured to drive the plurality of insulating elements (431(1) to 431(n)) in synchronization with the plurality of selected clock signals (CK(1)″ to CK(n)″).

### Supplementary Note 8

The signal transmitter (400) of any one of Supplementary Notes 1 to 7, wherein the oscillator circuit (510) includes a trimming circuit (506) configured to adjust an oscillation frequency of each of the plurality of clock signals (CK(1)-CK(n)).

### Supplementary Note 9

The signal transmitter (400) of any one of Supplementary Notes 1 to 8, wherein the oscillator circuit (510) is configured such that an oscillation frequency of each of the plurality of clock signals (CK(1) to CK(n)) has a negative temperature characteristic.

### Supplementary Note 10

The signal transmitter (400) of any one of Supplementary Notes 1 to 9, wherein each of the plurality of insulating elements (431(1) to 431(n)) is a transformer or a capacitor.

### Supplementary Note 11

A signal transmitter (400), including:
a transmission circuit (411);
a reception circuit (421); and
a plurality of insulating elements (431(1) to 431(n)) configured to transmit a plurality of signals (I11(1) to I11(n)), respectively, from the transmission circuit (411) to the reception circuit (421) while insulating between the transmission circuit (411) and the reception circuit (421),
wherein the transmission circuit (411) includes:
an oscillator circuit (510) configured to generate a clock signal (CK); and
a plurality of driving circuits (520(1) to 520(n)) configured to receive electric power from different power supply lines (PL1 and PL2) for each of a plurality of groups (GRP1 and GRP2) to which the plurality of driving circuits respectively belong, and to drive the plurality of insulating elements (431(1) to 431(n)) in synchronization with the clock signal (CK).

### Supplementary Note 12

An electronic device (A), including:
the signal transmitter (400) of any one of Supplementary Notes 1 to 11.

### Supplementary Note 13

A vehicle (B), including:
the electronic device (A) of Supplementary Note 12.

### Supplementary Note 14

An insulated gate driver IC, which is formed by integrating the signal transmitter (400) of any one of Supplementary Notes 1 to 11.

### Others

In addition to the above-described embodiments, the various technical features disclosed in this specification may be modified in various ways without departing from the spirit of the technical creation. In other words, the above-described embodiments should be considered to be exemplary and not limitative in all respects. Furthermore, the technical scope of this disclosure is defined by the claims, and should be understood to include all modifications that are equivalent in meaning and scope to the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A signal transmitter, comprising:
a transmission circuit;
a reception circuit; and
a plurality of insulating elements configured to transmit a plurality of signals, respectively, from the transmission circuit to the reception circuit while insulating between the transmission circuit and the reception circuit,
wherein the transmission circuit includes:
an oscillator circuit configured to generate a plurality of clock signals having different phases; and
a plurality of driving circuits configured to drive the plurality of insulating elements in synchronization with the plurality of clock signals, respectively.

2. The signal transmitter of claim 1, wherein the oscillator circuit includes:
an oscillator configured to generate a reference clock signal; and
a plurality of delay circuits connected in series,
wherein the reference clock signal is input to a delay circuit located most upstream among the plurality of delay circuits, and the plurality of clock signals are output from the plurality of delay circuits, respectively.

3. The signal transmitter of claim 1, wherein the oscillator circuit is a ring oscillator including a plurality of inverters connected in a ring shape, and
wherein the plurality of clock signals are output from the plurality of inverters, respectively.

4. The signal transmitter of claim 1, wherein the plurality of driving circuits are configured to drive the plurality of insulating elements in synchronization with both a rising edge and a falling edge of each of the plurality of clock signals.

5. The signal transmitter of claim 1, wherein the plurality of driving circuits are supplied with electric power from different power supply lines for each of a plurality of groups to which the plurality of driving circuits respectively belong.

6. The signal transmitter of claim 3, wherein the plurality of driving circuits are supplied with electric power from different power supply lines for each of a plurality of groups to which the plurality of driving circuits respectively belong, and
wherein the clock signals output from adjacent inverters among the plurality of inverters are output to driving circuits belonging to different groups among the plurality of driving circuits.

7. The signal transmitter of claim 1, further comprising:
a plurality of frequency divider circuits configured to divide frequencies of the plurality of clock signals, respectively, to generate a plurality of divided clock signals; and
a plurality of multiplexers configured to output one of the plurality of clock signals and the plurality of divided clock signals to the plurality of driving circuits, respectively, as a plurality of selected clock signals,
wherein the plurality of driving circuits are configured to drive the plurality of insulating elements in synchronization with the plurality of selected clock signals.

8. The signal transmitter of claim 1, wherein the oscillator circuit includes a trimming circuit configured to adjust an oscillation frequency of each of the plurality of clock signals.

9. The signal transmitter of claim 1, wherein the oscillator circuit is configured such that an oscillation frequency of each of the plurality of clock signals has a negative temperature characteristic.

10. The signal transmitter of claim 1, wherein each of the plurality of insulating elements is a transformer or a capacitor.

11. A signal transmitter, comprising:
a transmission circuit;
a reception circuit; and
a plurality of insulating elements configured to transmit a plurality of signals, respectively, from the transmission circuit to the reception circuit while insulating between the transmission circuit and the reception circuit,
wherein the transmission circuit includes:
an oscillator circuit configured to generate a clock signal; and
a plurality of driving circuits configured to receive electric power from different power supply lines for each of a plurality of groups to which the plurality of driving circuits respectively belong, and to drive the plurality of insulating elements in synchronization with the clock signal.

12. An electronic device, comprising:
the signal transmitter of claim 1.

13. A vehicle, comprising:
the electronic device of claim 12.

14. An insulated gate driver integrated circuit, which is formed by integrating the signal transmitter of claim 1.
